(19) United States
(12) Patent Application Publication
(10) Pub. No.: US 2026/0123045 A1
(43) Pub. Date: Apr. 30, 2026

(54) SEMICONDUCTOR DEVICE

(71) Applicant: Samsung Electronics Co., Ltd., Suwon-si (KR)

(72) Inventors: Jaein Kim, Suwon-si (KR); PANJAE PARK, Suwon-si (KR); Jisoo Park, Suwon-si (KR); BYUNG-SUNG KIM, Suwon-si (KR)

(21) Appl. No.: 19/240,249

(22) Filed: Jun. 17, 2025

(30) Foreign Application Priority Data
Oct. 29, 2024 (KR) 10-2024-0150023

(51) Int. Cl. H10D 84/90; H10D 89/10

(52) U.S. Cl. CPC H10D 84/931; H10D 84/953; H10D 89/10

(57) ABSTRACT

A semiconductor device according to an embodiment of the present disclosure includes: a substrate that includes a first surface and a second surface facing each other and includes a first device region and a second device region at which different conductivity types of devices are disposed; a first channel pattern and a second channel pattern that are each disposed above the first surface of the substrate at the first device region and the second device region; an insulating structure that extends in a first direction between the first device region and the second device region; gate structures that surround the first channel pattern and the second channel pattern and extend in a second direction intersecting the first direction; source/drain patterns that are connected to both sides of each of the first channel pattern and the second channel pattern; a lower wire that is disposed on the second surface of the substrate and is connected to at least some of the source/drain patterns and the gate structure disposed at one edge of the first device region; and a device separation film that penetrates the gate structure disposed at the other edge of the first device region.

### CROSS-REFERENCE TO RELATED APPLICATION

This application claims priority to and the benefit of Korean Patent Application No. 10-2024-0150023 filed at the Korean Intellectual Property Office on Oct. 29, 2024, the entire contents of which are herein incorporated by reference.

### BACKGROUND

### 1. Field

The present disclosure relates to a semiconductor device.

### 2. Description of the Related Art

A standard cell is one of design methods widely used in design of an integrated circuit (IC), and refers to a form in which small transistor blocks capable of being repeatedly used are disposed in a predefined method. Design using the standard cell may reduce complexity of the design, may improve productivity, and may ensure a certain level of performance and a certain level of electric power efficiency. However, as a semiconductor process becomes finer, problems such as interference between transistors and inefficient electric power consumption may occur, and a leakage electric current problem in a diffusion region negatively affect performance of the integrated circuit.

A diffusion break is one of technologies for solving the leakage electric current problem, and separates the diffusion region to serve to block an unnecessary flow of an electric current, reduce electric power consumption, and alleviate electrical interference between the transistors. The diffusion break is disposed at a boundary between a P-type region and an N-type region of the transistor to prevent continuous connection of a diffusion layer. Accordingly, it is possible to prevent deterioration in performance of a device and improve electric power efficiency.

The diffusion break is important in high-density integrated circuits, where the spacing between transistors becomes increasingly narrow as process nodes shrink. This reduced spacing increases the risk of electric current leakage, making diffusion breaks essential for maintaining device isolation and performance. Therefore, a diffusion break technology is an essential element in a latest process technology and is recognized as an important component in design of a high-performance and low-power semiconductor.

### SUMMARY

Embodiments are intended to effectively prevent leakage of an electric current by mixing and using various diffusion breaks according to a characteristic of a device.

A semiconductor device according to an embodiment of the present disclosure includes: a substrate that includes a first surface and a second surface facing each other and includes a first device region and a second device region at which different conductivity types of devices are disposed; a first channel pattern and a second channel pattern that are each disposed above the first surface of the substrate at the first device region and the second device region; an insulating structure that extends in a first direction between the first device region and the second device region; gate structures that surround the first channel pattern and the second channel pattern and extend in a second direction intersecting the first direction; source/drain patterns that are connected to both sides of each of the first channel pattern and the second channel pattern; a lower wire that is disposed on the second surface of the substrate and is connected to at least some of the source/drain patterns and the gate structure disposed at one edge of the first device region; and a device separation film that penetrates the gate structure disposed at the other edge of the first device region.

A semiconductor device according to another embodiment includes: a substrate that includes a first surface and a second surface facing each other and includes a first device region and a second device region at which different conductivity types of devices are disposed; a first channel pattern and a second channel pattern that are each disposed above the first surface of the substrate at the first device region and the second device region; insulating structures that extend in a first direction with the first channel pattern and the second channel pattern interposed therebetween and face each other in a second direction intersecting the first direction; gate structures that surround the first channel pattern and the second channel pattern and extend in the second direction; source/drain patterns that are connected to both sides of each of the first channel pattern and the second channel pattern; a lower wire that is disposed on the second surface of the substrate and is connected to at least some of the source/drain patterns and the gate structure disposed at one edge of the first device region; and a device separation film that penetrates the gate structure disposed at the other edge of the first device region.

A semiconductor device according to another embodiment includes: a substrate that includes a first surface and a second surface facing each other and includes a first device region and a second device region at which different conductivity types of devices are disposed; a first channel pattern and a second channel pattern that are disposed above the first surface of the substrate at the first device region and the second device region, respectively; at least one insulating structure that extends in a first direction and is disposed adjacent to at least one of the first channel pattern and the second channel pattern in a second direction intersecting the first direction; gate structures that surround the first channel pattern and the second channel pattern and extend in the second direction; source/drain patterns that are connected to both sides of each of the first channel pattern and the second channel pattern; and a lower wire that is disposed on the second surface of the substrate, is connected to at least some of the source/drain patterns, and is connected to the gate structures disposed at both edges of the first device region and the second device region.

According to embodiments, leakage of an electric current may be effectively prevented by mixing and using various diffusion breaks according to a characteristic of a device.

### BRIEF DESCRIPTION OF THE DRAWINGS

Each of FIG. 1 and FIG. 2 is a layout diagram showing a semiconductor device according to an embodiment of the present disclosure.

FIG. 3 is a cross-sectional view of the semiconductor device along line A-A′ of each of FIG. 1 and FIG. 2.

FIG. 4 is a cross-sectional view of the semiconductor device along line B-B′ of each of FIG. 1 and FIG. 2.

FIG. 5 is a cross-sectional view of the semiconductor device along line C-C′ of each of FIG. 1 and FIG. 2.

FIG. 6 is a cross-sectional view of the semiconductor device along line D-D′ of each of FIG. 1 and FIG. 2.

Each of FIG. 7 and FIG. 8 is a layout diagram showing a semiconductor device according to an embodiment of the present disclosure.

FIG. 9 is a cross-sectional view of the semiconductor device along line E-E′ of each of FIG. 7 and FIG. 8.

FIG. 10 is a cross-sectional view of the semiconductor device along line F-F′ of each of FIG. 7 and FIG. 8.

Each of FIG. 11 and FIG. 12 is a layout diagram showing a semiconductor device according to an embodiment of the present disclosure.

FIG. 13 is a cross-sectional view of the semiconductor device along line G-G′ of each of FIG. 11 and FIG. 12.

FIG. 14 is a cross-sectional view of the semiconductor device along line H-H′ of each of FIG. 11 and FIG. 12.

Each of FIG. 15 and FIG. 16 is a layout diagram showing a semiconductor device according to an embodiment of the present disclosure.

FIG. 17 is a cross-sectional view of the semiconductor device along line I-I′ of each of FIG. 15 and FIG. 16.

FIG. 18 is a cross-sectional view of the semiconductor device along line J-J′ of each of FIG. 15 and FIG. 16.

Each of FIG. 19 and FIG. 20 is a layout diagram showing a semiconductor device according to an embodiment of the present disclosure.

FIG. 21 is a cross-sectional view of the semiconductor device along line A-A′ of each of FIG. 19 and FIG. 20.

FIG. 22 is a cross-sectional view of the semiconductor device along line B-B′ of each of FIG. 19 and FIG. 20.

FIG. 23 is a cross-sectional view of the semiconductor device along line C-C′ of each of FIG. 19 and FIG. 20.

FIG. 24 is a cross-sectional view of the semiconductor device along line D-D′ of each of FIG. 19 and FIG. 20.

Each of FIG. 25 and FIG. 26 is a layout diagram showing a semiconductor device according to an embodiment of the present disclosure.

FIG. 27 is a cross-sectional view of the semiconductor device along line E-E′ of each of FIG. 25 and FIG. 26.

FIG. 28 is a cross-sectional view of the semiconductor device along line F-F′ of each of FIG. 25 and FIG. 26.

Each of FIG. 29 and FIG. 30 is a layout diagram showing a semiconductor device according to an embodiment of the present disclosure.

FIG. 31 is a cross-sectional view of the semiconductor device along line G-G′ of each of FIG. 29 and FIG. 30.

FIG. 32 is a cross-sectional view of the semiconductor device along line H-H′ of each of FIG. 29 and FIG. 30.

Each of FIG. 33 and FIG. 34 is a layout diagram showing a semiconductor device according to an embodiment of the present disclosure.

FIG. 35 is a cross-sectional view of the semiconductor device along line I-I′ of each of FIG. 33 and FIG. 34.

FIG. 36 is a cross-sectional view of the semiconductor device along line J-J′ of each of FIG. 33 and FIG. 34.

### DETAILED DESCRIPTION

Embodiments of the present disclosure will be described more fully hereinafter with reference to the accompanying drawings so that those skilled in the art could easily implement the embodiments. The present disclosure may be modified in various ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

In the drawings, a size and a thickness of each element are arbitrarily illustrated for ease of description, and the present disclosure is not necessarily limited to those illustrated in the drawings. In the drawings, the thicknesses of some layers and areas are exaggerated for clarity. In the drawings, for ease of description, the thicknesses of some layers and areas are exaggerated.

It should be understood that when an element such as a layer, a film, a region, or a plate is referred to as being “on” or “above” another element, it may be directly on the other element, or an intervening element may also be present. In contrast, when an element is referred to as being “directly on” another element, there is no intervening element present. Further, in the specification, the word “on” or “above” means disposed on or below a referenced part, and does not necessarily mean disposed on the upper side of the referenced part based on a gravitational direction.

Unless explicitly stated to the contrary, the word “comprise” and variations such as “comprises” and “comprising” should be understood to imply the inclusion of stated elements but not the exclusion of any other elements.

Throughout the specification, the phrase “in a plan view” or “on a plane” may mean when an object portion is viewed from above, and the phrase “in a cross-sectional view” or “on a cross-section” may mean when a cross-section taken by vertically cutting an object portion is viewed from the side.

Throughout the specification, two directions parallel to and intersecting an upper surface of a substrate are each defined as a first direction D1 and a second direction D2, and a direction perpendicular to the upper surface of the substrate is described as a third direction D3. For example, the first direction D1 and the second direction D2 may be orthogonal to each other.

Throughout the specification, the upper surface of the substrate may be referred to as a front side, and a lower surface of the substrate may be referred to as a back side.

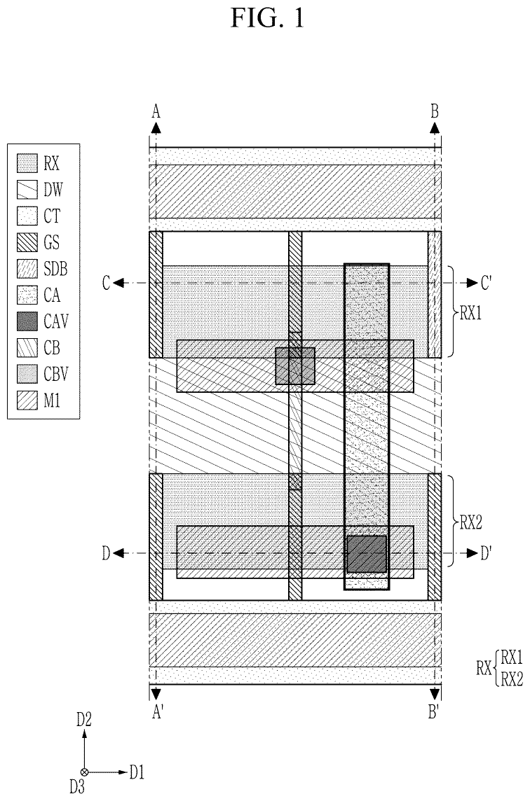

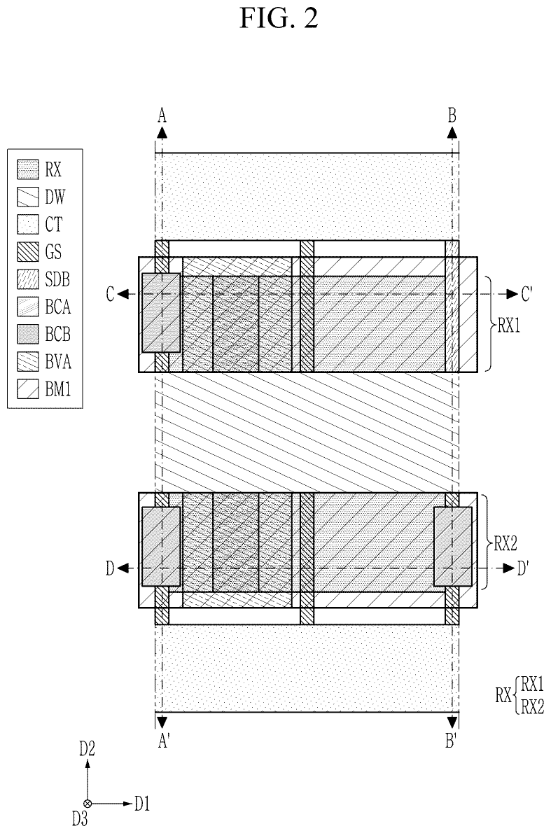

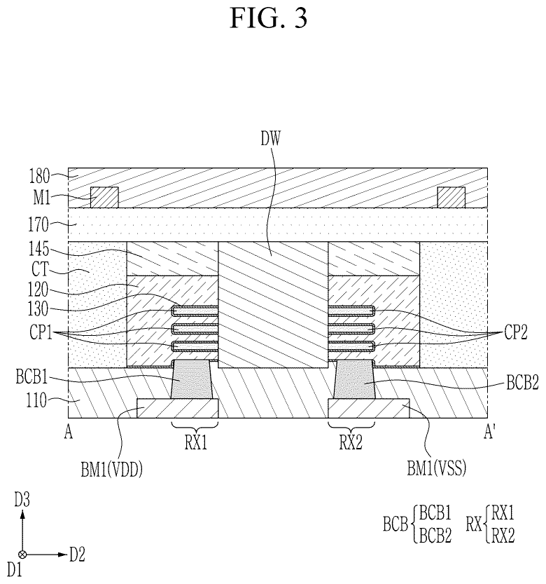

FIGS. 1 to 6 illustrate a structure in which a lower metal line BM1 is electrically connected to a gate structure GS positioned at one edge of a first active region RX1, while a device separation film SDB, extending through a gate structure GS located at the opposite edge of the first active region RX1, is formed to provide electrical isolation. Both the lower metal line BM1 and the device separation film SDB are disposed within the first active region RX1, which forms part of a unit cell in a semiconductor device in accordance with an embodiment of the present disclosure. Furthermore, a lower metal line connected to gate structures formed at opposite boundaries of a second active region RX2 is disposed within the second active region RX2. Hereinafter, for clear understanding and convenience of the description, FIG. 1 and FIG. 2 will be first described, and FIGS. 3 to 6 will be later described. Throughout the specification, the device separation film SDB and a lower gate pattern BCB connecting the gate structure GS to the lower wire BM1 may be referred to as a diffusion break.

Each of FIG. 1 and FIG. 2 is a layout diagram showing the semiconductor device according to an embodiment of the present disclosure. FIG. 1 is a layout diagram showing a first surface (e.g., a front side) of the semiconductor device according to an embodiment of the present disclosure. FIG. 2 is a layout diagram showing a second surface (e.g., a back side) of the semiconductor device according to an embodiment of the present disclosure.

Referring to FIG. 1 and FIG. 2, the semiconductor device according to the embodiment may include gate structures GS disposed at the first and second device regions RX1 and RX2 of a substrate, an insulating structure DW and a gate separation structure CT separating the gate structures GS, the device separation film SDB disposed at an edge of the first device region RX1, an upper wire M1 disposed above or on an upper surface of the substrate, and the lower wire BM1 disposed above or on a lower surface of the substrate. The semiconductor device according to the embodiment may further include a contact pattern CA connected to an upper wire M1, a contact via CAV, a gate via CBV, a lower contact pattern BCA connected to the lower wire BM1, the lower gate pattern BCB, and a lower via BVA.

According to an embodiment, the gate structures GS, the contact pattern CA, a gate pattern CB, the upper wire M1, the lower wire BM1, the lower via BVA, the lower contact pattern BCA, and the lower gate pattern BCB disposed at the first and second device regions RX1 and RX2 may form one standard cell. The first device region RX1 and the second device region RX2 may be disposed within the one standard cell.

For convenience of description, FIG. 1 shows only a portion of the standard cell included in the semiconductor device, and the standard cell may be designed to further include other components. In the present disclosure, the semiconductor device may be referred to as an integrated circuit or a semiconductor apparatus.

According to an embodiment, the semiconductor device may include a plurality of standard cells. The standard cell may be a unit of layout included in an integrated circuit chip, and may be simply referred to as a cell or a unit cell. The integrated circuit chip may include a plurality of various standard cells, and the standard cells may have a structure that complies with predetermined rules based on a semiconductor process for manufacturing the integrated circuit chip. The standard cell may refer to a unit of a chip in which a size of layout thereof satisfies a predetermined rule and having a predetermined function. According to an embodiment, the standard cell may include an input pin and an output pin, and may output a signal through the output pin by processing a signal received through the input pin. For example, the standard cell may correspond to a basic cell such as an AND element, an OR element, a NOR element, and an inverter, a complex cell such as an OAI (OR/AND/INVERTER) and an AOI (AND/OR/INVERTER), or a storage element such as a simple master-slave flip-flop and a latch. According to an embodiment, the standard cell may have a quadrangular shape, but is not limited to the shape.

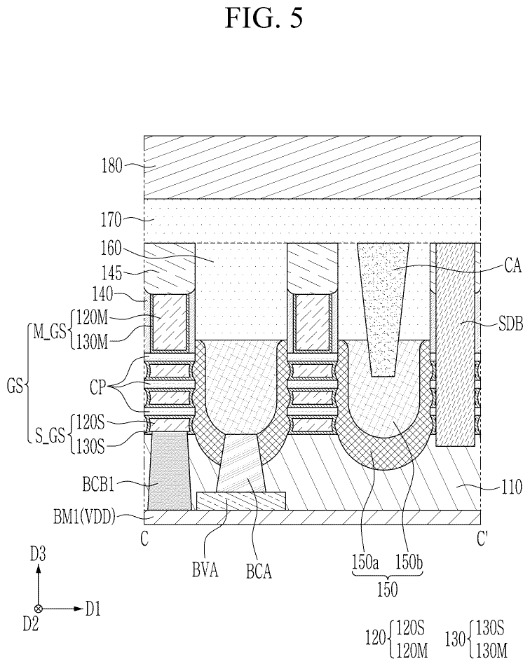

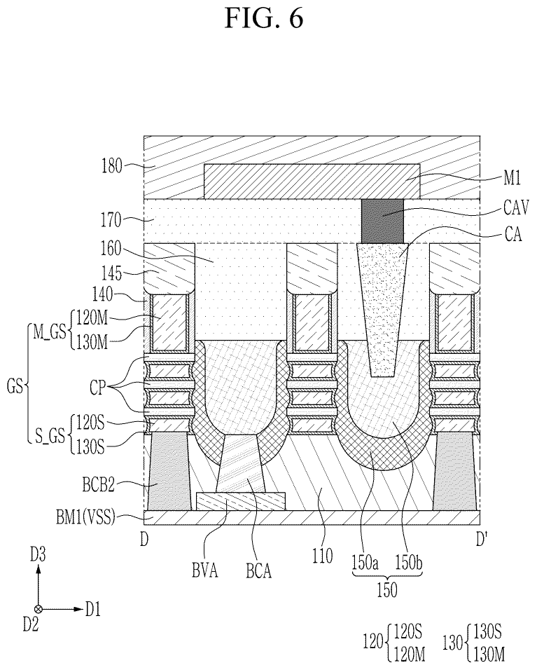

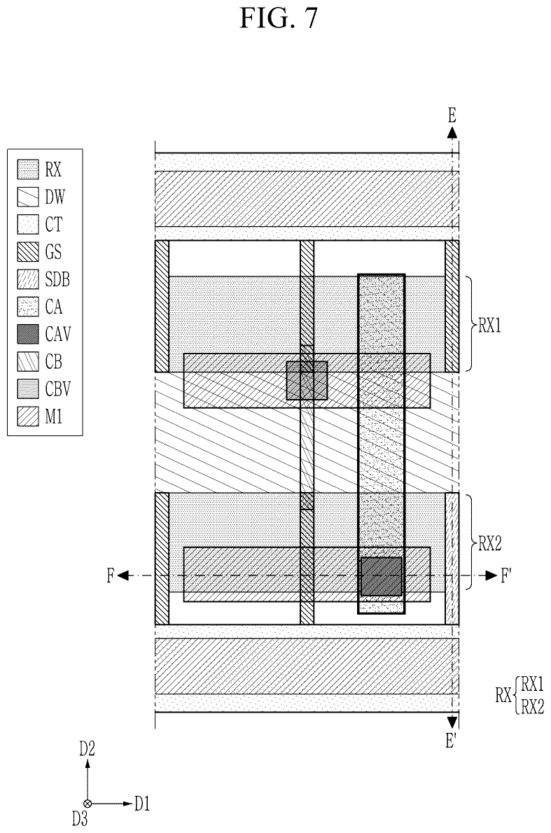

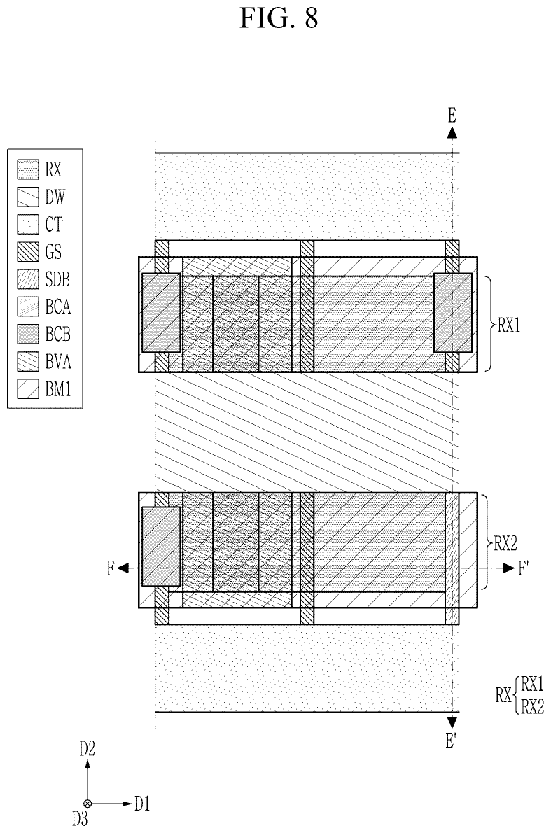

The semiconductor device according to the embodiment may include the upper wire M1 and the lower wire BM1, and may implement an electric power distribution network using the upper wire M1 and the lower wire BM1. Accordingly, some of signals and/or electric power applied to source/drain patterns 150 (e.g., source/drain patterns 150 of FIG. 5 and FIG. 6) and/or the gate structures GS of the first and second device regions RX1 and RX2 may be transferred through the upper wiring M1, and the rest thereof may be transferred through the lower wire BM1.

According to an embodiment, each of a plurality of unit cells may include device regions RX having a predetermined width in the second direction D2 and extending along the first direction D1. A transistor (or a device) including gate electrodes, a channel pattern with multiple sub-channel patterns stacked in the third direction D3, and source/drain patterns to be later described may be disposed at the device region RX. According to an embodiment, the device region RX may include the first device region RX1, and the second device region RX2 disposed adjacent to the first device region RX1, having a predetermined width in the second direction D2, and extending along the first direction D1. According to an embodiment, widths (e.g., widths along the second direction D2) of the first device region RX1 and the second device region RX2 may be similar or substantially the same.

According to an embodiment, different types (i.e., conductivity types) of devices may be disposed at the first device region RX1 and the second device region RX2. According to an embodiment, a first type transistor may be disposed at the first device region RX1, and a second type transistor different from the first type transistor may be disposed at the second device region RX2. For example, a source/drain pattern included in the first type transistor may include or may be doped with one of a P-type dopant and an N-type dopant, and a source/drain pattern included in the second type transistor may include or may be doped with the other of the P-type dopant and the N-type dopant. For convenience of description, in embodiments below, it will be described that a source/drain pattern disposed at the first device region RX1 includes or is doped with a P-type dopant and a source/drain pattern disposed at the second device region RX2 includes or is doped with an N-type dopant. In other words, in the embodiments below, the first device region RX1 may be a PMOS transistor region, and the second device region RX2 may be an NMOS transistor region. In an embodiment, each of the first device region RX1 and the second device region RX2 may serve as an active region in which a transistor is formed. In an embodiment, the first device region RX1 and the second device region RX2 may be a planar active region or a fin-type active region.

Although not clearly illustrated in the drawings, each of the plurality of unit cells may include the first device region RX1 and the second device region RX2, and the first device region RX1 and the second device region RX2 may be alternately disposed adjacent to each other along the second direction D2. However, the present disclosure is not limited thereto, and each of the plurality of unit cells may include the first device region RX1 and the second device region RX2, first device regions RX1 may be disposed adjacent to each other along the second direction D2, and second device regions RX2 may be disposed adjacent to each other along the second direction D2. According to an embodiment, the first device region RX1 and the second device region RX2 may be formed above or on the substrate. For example, the substrate may be made of an insulating material.

According to an embodiment, the first device region RX1 and the second device region RX2 at which a plurality of channel patterns to be later described are disposed, and the insulating structure DW separating the first device region RX1 and the second device region RX2 may be disposed above or on the substrate. Each of the first device region RX1, the insulating structure DW, and the second device region RX2 may extend along the first direction D1. The first device region RX1, the insulating structure DW, and the second device region RX2 may be disposed along the second direction D2. In other words, the insulating structure DW may extend in the first direction D1 between the first device region RX1 and the second device region RX2.

According to an embodiment, the insulating structure DW may be in contact with a first channel pattern CP1 and a second channel pattern CP2 described later in the second direction D2. In other words, the insulating structure DW may not be spaced apart from the first channel pattern CP1 and the second channel pattern CP2 in the second direction D2. However, the present disclosure is not limited thereto, and a gate insulating film 130 later described may be interposed between the insulating structure DW and the first and second channel patterns CP1 and CP2. At least a portion of a gate electrode 120 described below may be interposed between the insulating structure DW and the first and second channel patterns CP1 and CP2.

As described above, because the insulating structure DW of the semiconductor device according to the present disclosure is not spaced apart from the first channel pattern CP1 and the second channel pattern CP2 in the second direction D2, it is possible to physically and/or electrically separate the first device region RX1 and the second device region RX2 while increasing a degree of integration of the device.

As described below, the plurality of channel patterns may be disposed above or on an upper surface of the substrate. The plurality of channel patterns may be disposed along the second direction D2. The plurality of channel patterns may include the first channel pattern CP1 formed at the first device region RX1 and the second channel pattern CP2 formed at the second device region RX2. According to an embodiment, the plurality of channel patterns may be surrounded by the gate structure GS and the insulating structure DW.

According to an embodiment, the semiconductor device may include a plurality of gate structures GS surrounding the plurality of channel patterns and extending along the second direction D2. According to an embodiment, the gate structures GS may have a shape extending along the second direction D2 inside the standard cell. According to an embodiment, the gate structures GS may have a shape separated along the second direction D2 by the insulating structure DW. According to an embodiment, at least some of the plurality of gate structures GS may be disposed at one edge of the first device region RX1 and/or the second device region RX2.

According to an embodiment, a pitch between the plurality of gate structures GS may be referred to as a 1 contacted poly pitch (CPP). For example, the 1 CPP is the minimum distance from the center of one gate structure (the gate of a transistor with a contact on it) to the center of the next one, in the same direction. The number of the gate structures GS of the present specification is only an example, and it is obvious that a cell configured to have a different number of the gate structures GS from the number is possible.

According to an embodiment, the semiconductor device may further include the gate separation structure CT that separates and spaces the gate structures GS extending along the second direction D2. According to an embodiment, the gate separation structure CT may be disposed between adjacent channel patterns CP later described along the second direction D2.

According to an embodiment, the gate separation structure CT may be disposed adjacent to edges of one side (e.g., an upper side) and the other side (e.g., a lower side) of the standard cell. Some of gate separation structures CT may have a shape that overlaps the upper wire M1 and extends along the first direction D1.

According to an embodiment, some of the gate separation structures CT may be disposed to face the insulating structure DW with the first device region RX1 interposed therebetween. According to an embodiment, some of the gate separation structures CT may be disposed to face the insulating structure DW with the second device region RX2 therebetween.

According to an embodiment, the gate separation structure CT may be spaced apart from the first channel pattern CP1 disposed at the first device region RX1 in the second direction D2. According to an embodiment, the gate separation structure CT may be spaced apart from the second channel pattern CP2 disposed at the second device region RX2 in the second direction D2.

According to an embodiment, contact patterns CA may be disposed above or on at least one source/drain pattern 150 of the first device region RX1 and/or the second device region RX2. According to an embodiment, the contact pattern CA may be disposed above or on the source/drain patterns 150 to be electrically connected to the source/drain patterns 150.

According to an embodiment, the contact pattern CA may be connected to the upper wire M1 through the contact via CAV. For example, the contact via CAV may include aluminum, copper, tungsten, molybdenum, cobalt, or a combination thereof.

According to an embodiment, the gate pattern CB may be disposed above or on at least one gate structure GS of the first device region RX1 and/or the second device region RX2. For example, the gate pattern CB may be disposed on at least one gate electrode 120 that will be described later. In this way, the gate pattern CB may be disposed on the gate electrodes to be electrically connected to the gate electrodes.

According to an embodiment, gate patterns CB may be connected to the upper wire M1 through the gate via CBV. For example, the gate via CBV may include aluminum, copper, tungsten, molybdenum, cobalt, or a combination thereof.

According to an embodiment, the upper wire M1 may include a plurality of conductive patterns or a plurality of patterns made of a conductive material. In the present specification, the pattern may refer to a conductive pattern. For example, the upper wire M1 may include each of upper wire patterns extending along the first direction D1. In this case, the pattern extending in one direction may be referred to as a line, so that the upper wire patterns are referred to as upper wire lines. According to an embodiment, the gate electrode 120 later described may be connected to the upper wire M1 through the gate pattern CB.

According to an embodiment, the semiconductor device may include the device separation film SDB that physically separates cells adjacent to each other. According to an embodiment, channel patterns of the cell may be terminated by the device separation film SDB. The device separation film SDB may be inserted to reduce an influence between cells adjacent to each other (e.g., a local layout effect (LLE)), and may separate impurity-doped regions between the cells adjacent to each other. According to an embodiment, the device separation film SDB may be made of an insulating material.

According to an embodiment, the device separation film SDB may be disposed adjacent to an edge (or a boundary) of the cell. In the present disclosure, the device separation film SDB is illustrated as being a single diffusion break, but the present disclosure is not limited thereto, and the device separation film SDB may be a double diffusion break.

According to an embodiment, the device separation film SDB may penetrate the gate structure GS disposed at one edge (e.g., a left side or a right side) of the cell in the third direction D3. A width (e.g., a length along the first direction D1) of the device separation film SDB may be less than or substantially the same as a width of the gate structure GS. For example, if the width (or the length along the first direction D1) of the device separation film SDB is less than the width of the gate structure GS, gate structures GS that are not removed may be disposed around the device separation film SDB. For example, the same material as those of the gate structures GS may be disposed to be in contact with the outside of the device separation film SDB. For example, if the width (or the length along the first direction D1) of the device separation film SDB is substantially the same as the width of the gate structure GS, the device separation film SDB may be in direct contact with a first interlayer insulating layer (e.g., a first interlayer insulating layer 160 of FIG. 5 and FIG. 6) described below.

Referring to FIG. 1 and FIG. 2, in an embodiment, the device separation film SDB disposed adjacent to one edge of the cell may be disposed at the first device region RX1. In FIG. 1 and FIG. 2, the device separation film SDB is illustrated as being disposed adjacent to a right edge of the cell, but the present disclosure is not limited thereto, and the device separation film SDB may be disposed adjacent to a left edge of the cell.

According to an embodiment, the device separation film SDB may physically separate one side of the first device region RX1 from a region of another cell adjacent to the one side of the first device region RX1. In this case, the first channel pattern CP1 may be removed at a portion intersecting the device separation film SDB. For example, the device separation film SDB may not overlap the first channel pattern CP1 in the third direction D3.

According to an embodiment, one gate structure GS disposed at one edge (e.g., a left side or a right side) of the first device region RX1 among the plurality of gate structures GS may be replaced with the device separation film SDB. For example, the device separation film SDB may be formed by removing the gate structure GS and filling the removed position with an insulating material. Therefore, it may be configured so that no electric current substantially flows between components disposed at both sides (i.e., opposite sides) of the device separation film SDB.

According to an embodiment, the semiconductor device may be disposed above or on a lower surface of the substrate, and may include the lower wire BM1 connected to at least some of the source/drain patterns 150 described below. According to an embodiment, at least some of the source/drain patterns 150 may be electrically connected to the lower wire BM1 via the lower contact pattern BCA.

According to an embodiment, the lower contact pattern BCA may extend along the second direction D2 between the gate structures GS. For example, the lower contact pattern BCA may be connected to the source/drain pattern 150 of the first device region RX1 and the source/drain pattern 150 of the second device region RX2.

According to an embodiment, the lower via BVA may be disposed between the lower contact pattern BCA and the lower wire BM1. In other words, the lower contact pattern BCA may be electrically connected to the lower wire BM1 through the lower via BVA. For example, the lower via BVA may include aluminum, copper, tungsten, molybdenum, cobalt, or a combination thereof.

According to an embodiment, the lower wire BM1 may overlap the first channel pattern CP1 and the second channel pattern CP2 in the third direction D3, and may extend along the first direction D1. However, the present disclosure is not limited thereto, and a disposition and/or an extension direction of the lower wire BM1 may be variously changed according to an embodiment.

According to an embodiment, the lower wire BM1 may include a first lower wire BM1(VDD) to which a first voltage (e.g., VDD) is applied, and a second lower wire BM1(VSS) to which a second voltage (e.g., VSS) lower than the first voltage is applied. According to an embodiment, the first voltage may be a positive voltage, and the second voltage may be a negative voltage or a ground voltage. According to an embodiment, the first lower wire BM1(VDD) may be disposed at the first device region RX1, and the second lower wire BM1(VSS) may be disposed at the second device region RX2.

According to an embodiment, the lower wire BM1 may be connected to the gate structure GS disposed at one edge of the first device region RX1 and/or the second device region RX2. Referring to FIG. 1 and FIG. 2, the lower wire BM1 may be connected to the gate structure GS disposed at one edge of the first device region RX1. The lower wire BM1 may be connected to gate structures GS disposed at both edges (i.e., opposite edges) of the second device region RX2.

According to an embodiment, the lower gate pattern BCB may be disposed between the lower wire BM1 and the gate structure GS. According to an embodiment, the first device region RX1 may include the lower gate pattern BCB connecting the gate structure GS disposed at one edge of the first device region RX1 and the first lower wire (e.g., a VDD wire) to which the first voltage is applied. According to an embodiment, the second device region RX2 may include the lower gate pattern BCB connecting the gate structures GS disposed at both edges of the second device region RX2 and the second lower wire (e.g., a VSS wire) to which the second voltage lower than the first voltage is applied.

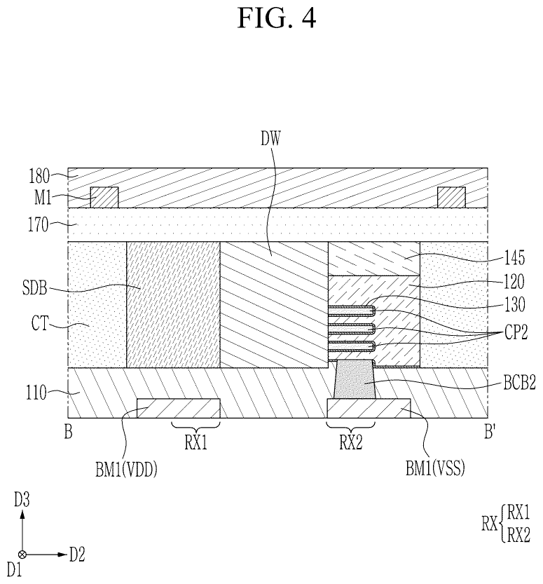

FIG. 3 is a cross-sectional view of the semiconductor device along line A-A′ of each of FIG. 1 and FIG. 2. FIG. 4 is a cross-sectional view of the semiconductor device along line B-B′ of each of FIG. 1 and FIG. 2. FIG. 5 is a cross-sectional view of the semiconductor device along line C-C′ of each of FIG. 1 and FIG. 2. FIG. 6 is a cross-sectional view of the semiconductor device along line D-D′ of each of FIG. 1 and FIG. 2.

Referring to FIGS. 3 to 6, the semiconductor device according to the embodiment may include a substrate 110, the first and second channel patterns CP1 and CP2, the gate structures GS, the insulating structure DW, the source/drain pattern 150, the gate separation structure CT, the device separation film SDB, the upper wire M1, and the lower wire BM1.

According to an embodiment, the substrate 110 may include an insulating material. The substrate 110 may include oxide, nitride, oxynitride, or a combination thereof. For example, the substrate 110 may include silicon nitride (SiNx). Although the substrate 110 is shown as a single film in the drawings, this is only for ease of description, and the present disclosure is not limited thereto.

A first surface and a second surface of the substrate 110 may be formed as a plane parallel to the first direction D1 and the second direction D2 intersecting the first direction D1. For example, the first surface of the substrate 110 may be an upper surface, and the second surface of the substrate 110 may be a lower surface. The upper surface of the substrate 110 may be a surface opposite to the lower surface of the substrate 110 in the third direction D3. The third direction D3 may be a direction perpendicular to the first direction D1 and the second direction D2. The upper surface of the substrate 110 may be referred to as a front side of the substrate 110, and the lower surface of the substrate 110 may be referred to as a back side of the substrate 110. In some embodiments, a logic circuit of a cell region may be implemented above or on the upper surface of the substrate 110. In some embodiments, a lower wiring structure may be disposed above or on the lower surface of the substrate 110.

According to an embodiment, the substrate 110 may include the first device region RX1 and the second device region RX2. The first device region RX1 and the second device region RX2 may be defined by the first and second channel patterns CP1 and CP2 and the source/drain patterns 150 disposed above or on the substrate 110. In other words, the first channel pattern CP1 and the source/drain pattern 150 doped with a first impurity (e.g., a P-type impurity) may be disposed at the first device region RX1, and the second channel pattern CP2 and the source/drain pattern 150 doped with a second impurity (e.g., an N-type impurity) may be disposed at the second device region RX2. As described above, in the present embodiment, the first device region RX1 may be a PMOS transistor region, and the second device region RX2 may be an NMOS transistor region.

According to an embodiment, the first channel pattern CP1 may be disposed at the first device region RX1. According to an embodiment, the first channel pattern CP1 may be disposed to be spaced apart in the first direction D1 above the upper surface of the substrate 110. According to an embodiment, multiple sub-channel patterns of the first channel pattern CP1 may be disposed to be spaced apart from each other in the third direction D3. For example, each of the multiple sub-channel patterns of the first channel pattern CP1 may have a sheet shape. Each sub-channel pattern of the first channel pattern CP1 may be a nanosheet with a thickness of several nanometers along the third direction D3.

According to an embodiment, the first channel pattern CP1 may provide a path through which an electric current flows between the source/drain patterns 150 described below. For example, the first channel pattern CP1 may be disposed between the source/drain patterns 150 to connect two adjacent source/drain patterns 150 with each other.

According to an embodiment, the first channel pattern CP1 may penetrate a portion of the gate structure GS in a direction (e.g., the first direction D1) that intersects a direction in which the gate structure GS extends. Although FIGS. 3 to 6 illustrate that three sub-channel patterns of the first channel pattern CP1 are disposed to be spaced apart from each other in the third direction D3, the present disclosure is not limited thereto, and the stacking number of the sub-channel patterns of the first channel pattern CP1 may be variously changed.

According to an embodiment, the second channel pattern CP2 may be disposed at the second device region RX2. According to an embodiment, the second channel patterns CP2 may be disposed to be spaced apart in the first direction D1 above the upper surface of the substrate 110. According to an embodiment, multiple sub-channel patterns of the second channel pattern CP2 may be disposed to be spaced apart from each other in the third direction D3. For example, each of the multiple sub-channel patterns of the second channel pattern CP2 may have a sheet shape. Each sub-channel pattern of the second channel pattern CP2 may be a nanosheet with a thickness of several nanometers along the third direction D3.

According to an embodiment, the second channel pattern CP2 may provide a path through which an electric current flows between the source/drain patterns 150 described below. For example, the second channel pattern CP2 may be disposed between the source/drain patterns 150 to connect two adjacent source/drain patterns 150 with each other.

According to an embodiment, the second channel pattern CP2 may penetrate a portion of the gate structure GS in a direction (e.g., the first direction D1) that intersects a direction in which the gate structure GS extends. Although FIGS. 3 to 6 illustrate that three sub-channel patterns of the second channel pattern CP2 are disposed to be spaced apart from each other in the third direction D3, the present disclosure is not limited thereto, and the stacking number of the sub-channel patterns of the second channel pattern CP2 may be variously changed.

According to an embodiment, each of the first and second channel patterns CP1 and CP2 may include a semiconductor material. For example, each of the first and second channel patterns CP1 and CP2 may include a Group IV semiconductor such as Si and Ge, a Group III-V compound semiconductor, or a Group II-VI compound semiconductor.

According to an embodiment, the gate structure GS may be disposed on the substrate 110. According to an embodiment, the gate structure GS may extend in the second direction D2 on the substrate 110. The gate structures GS may be disposed to be spaced apart from each other in the first direction D1. The gate structure GS may include a plurality of sub-gate structures S_GS and a main gate structure M_GS. The sub-gate structure S_GS may be disposed on the substrate 110, and the main gate structure M_GS may be disposed above the sub-gate structure S_GS.

Each of the sub-gate structures S_GS may be formed of several layers. For example, each of the sub-gate structures S_GS may include a sub-gate electrode 120S and a sub-gate insulating film 130S. In the first device region RX1, the sub-gate structures S_GS and the multiple sub-channel patterns of the first channel pattern CP1 may be alternately stacked in the third direction D3. In the second device region RX2, the sub-gate structures S_GS and the multiple sub-channel patterns of the second channel pattern CP2 may be alternately stacked in the third direction D3.

In FIGS. 3 to 6, three sub-gate structures S_GS are disposed to be spaced apart from each other in the third direction D3, but the number of sub-gate structures S_GS disposed to be spaced apart is not limited thereto. For example, the gate structure GS may include four sub-gate structures S_GS.

Referring to FIG. 3 and FIG. 4, the sub-gate electrode 120S may wrap at least some of the multiple sub-channel patterns of the first channel pattern CP1 and/or the second channel patterns CP2. For example, in the first device region RX1, the sub-gate electrode 120S may wrap at least some of the multiple sub-channel patterns of the first channel pattern CP1. For example, the sub-gate electrode 120S and the insulating structure DW later described may wrap the multiple sub-channel patterns of the first channel pattern CP1. In addition, for example, in the second device region RX2, the sub-gate electrode 120S may wrap at least some of the multiple sub-channel patterns of the second channel pattern CP2. For example, the sub-gate electrode 120S and the insulating structure DW later described may wrap the multiple sub-channel patterns of the second channel patterns CP2.

The sub-gate electrode 120S may include at least one of a metal, a metal alloy, conductive metal nitride, metal silicide, a doped semiconductor material, conductive metal oxide, and conductive metal oxynitride. For example, the sub-gate electrode 120S may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbon-nitride (TiAlC—N), titanium aluminum carbide (TiAlC), titanium carbide (TiC), tantalum carbon nitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Au), gold (Au), zinc (Zn), vanadium (V), and a combination thereof, but the present disclosure is not limited thereto. The conductive metal oxide and the conductive metal nitride may include an oxidized form of the above-described material, but the present disclosure is not limited thereto.

The sub-gate insulating film 130S may extend along the upper surface of the substrate 110. The sub-gate insulating film 130S may be disposed along a circumference of a plurality of sub-gate electrodes 120S. The sub-gate insulating film 130S may be in direct contact with the upper surface of the substrate 110 and the multiple sub-channel patterns of each of first and second channel patterns CP1 and CP2. The sub-gate insulating film 130S may be interposed between the multiple sub-channel patterns of each of the first and second channel patterns CP1 and CP2 and the plurality of sub-gate electrodes 120S. The sub-gate insulating film 130S may include various insulating materials. Although not shown in FIGS. 3 to 6, the semiconductor device according to the embodiment may further include an internal gate spacer disposed between the sub-gate insulating film 130S and the source/drain patterns 150 described below.

In an embodiment, the sub-gate insulating film 130S is shown as a single film in the drawings, but the present disclosure is not limited thereto. For example, the sub-gate insulating film 130S may be formed of a multiple film including silicon oxide (SiO₂) and a high dielectric constant material. In this case, the high dielectric constant material may include a material with a dielectric constant greater than that of silicon oxide (SiO₂). For example, the high dielectric constant material may include hafnium oxide (HfO), aluminum oxide (AlO), or tantalum oxide (TaO).

According to an embodiment, the main gate structure M_GS may be disposed above or on the sub-gate structure S_GS and the multiple sub-channel patterns of the first and second channel patterns CP1 and CP2. The main gate structure M_GS may be disposed on upper surfaces of uppermost sub-channel pattern of the multiple sub-channel patterns of the first and second channel patterns CP1 and CP2.

Referring to FIG. 3 and FIG. 4, at least a portion of the gate electrode 120 may be disposed on a structure in which the sub-gate electrode 120S and the multiple sub-channel patterns of the first and second channel patterns CP1 and CP2 are alternately stacked. Another portion of the gate electrode 120 may be formed to cover one side surface of the structure in which the sub-gate electrode 120S and the multiple sub-channel patterns of the first and second channel patterns CP1 and CP2 are alternately stacked. According to an embodiment, the gate insulating film 130 may be interposed between the gate electrode 120 and the multiple sub-channel patterns of the first and second channel patterns CP1 and CP2. In this case, three surfaces of each of the multiple sub-channel patterns of the first and second channel patterns CP1 and CP2 may be surrounded by the gate electrode 120, and one surface of each of the multiple sub-channel patterns of the first and second channel patterns CP1 and CP2 may be surrounded by the insulating structure DW later described.

According to an embodiment, the main gate structure M_GS may include a main gate electrode 120M and a main gate insulating film 130M.

According to an embodiment, the main gate electrode 120M may be disposed above or on the sub-gate structure S_GS and the multiple sub-channel patterns of the first and second channel patterns CP1 and CP2. The main gate electrode 120M may include the same material as that of the sub-gate electrode 120S. For example, the main gate electrode 120M may include at least one of a metal, a metal alloy, conductive metal nitride, metal silicide, a doped semiconductor material, conductive metal oxide, and conductive metal oxynitride.

According to an embodiment, the main gate insulating film 130M may extend along a side surface and a lower surface of the main gate electrode 120M. The main gate insulating film 130M may extend along a side surface of a gate spacer 140 described below. The main gate insulating film 130M may include various insulating materials.

In an embodiment, the main gate insulating film 130M is shown as a single film in the drawings, but the present disclosure is not limited thereto. For example, the main gate insulating film 130M may be formed of a multiple film including silicon oxide (SiO₂) and a high dielectric constant material. In this case, the high dielectric constant material may include a material with a dielectric constant greater than that of silicon oxide (SiO₂). For example, the high dielectric constant material may include hafnium oxide (HfO), aluminum oxide (AlO), or tantalum oxide (TaO).

According to an embodiment, the insulating structure DW may be disposed between the first device region RX1 and the second device region RX2 on the substrate 110. According to an embodiment, the insulating structure DW may extend in the first direction D1.

According to an embodiment, an upper surface of the insulating structure DW may be disposed at a higher level than those of the upper surfaces of the first and second channel patterns CP1 and CP2 disposed at an uppermost portion. In other words, the upper surface of the insulating structure DW may be disposed farther from the upper surface of the substrate 110 than the upper surfaces of the uppermost first and second channel patterns CP1 and CP2. According to an embodiment, the upper surface of the insulating structure DW may be disposed at a higher level than that of an upper surface of the gate structure GS. In other words, the upper surface of the insulating structure DW may be disposed farther from the upper surface of the substrate 110 than an upper surface of an uppermost gate structure GS.

As shown in FIG. 3, the insulating structure DW may be disposed between a side surface of the first channel pattern CP1 and a side surface of the second channel pattern CP2. According to an embodiment, the insulating structure DW may be in contact with the first channel pattern CP1 and the second channel pattern CP2 in the second direction D2. In other words, the insulating structure DW may not be spaced apart from the first channel pattern CP1 and the second channel pattern CP2 in the second direction D2. For example, one side of the insulating structure DW may be in contact with the first channel pattern CP1, and the other side of the insulating structure DW may be in contact with the second channel pattern CP2. However, unlike the illustration in the drawings, the gate insulating film 130 may be interposed between the insulating structure DW and the first and second channel patterns CP1 and CP2.

Additionally, as shown in FIG. 3, the insulating structure DW may be in contact with a side surface of the gate structure GS disposed between the first channel patterns CP1 adjacent to each other in the third direction D3. A side surface of the insulating structure DW may be in contact with a side surface of a stacking structure in which the gate structure GS and the first channel patterns CP1 are alternately stacked. In other words, the side surface of the insulating structure DW may not be spaced apart from the side surface of the stacking structure in which the gate structure GS and the first channel patterns CP1 are alternately stacked in the second direction D2.

According to an embodiment, the insulating structure DW may be in contact with the side surface of the gate structure GS disposed between the multiple sub-channel patterns of the second channel pattern CP2 adjacent to each other in the third direction D3. The side surface of the insulating structure DW may be in contact with a side surface of a stacking structure in which the gate structure GS and the multiple sub-channel patterns of the second channel pattern CP2 are alternately stacked. In other words, the side surface of the insulating structure DW may not be spaced apart from the side surface of the stacking structure in the second direction D2. In the stacking structure, the gate structure GS and the multiple sub-channel patterns of the second channel pattern CP2 are alternately stacked in the third direction D3.

As shown in FIG. 4, the insulating structure DW may be disposed between the side surface of the second channel pattern CP2 and the device separation film SDB described below. According to an embodiment, the insulating structure DW may be in contact with the second channel pattern CP2 in the second direction D2. According to an embodiment, the insulating structure DW may be in contact with the device separation film SDB in the second direction D2. For example, one side of the insulating structure DW may be in contact with the second channel pattern CP2, and the other side of the insulating structure DW may be in contact with the device separation film SDB.

The insulating structure DW may perform a function of a gate separation structure that insulates or isolates the gate structures GS from one another. According to an embodiment, the source/drain pattern 150 may be disposed at each of one side and the other side along the second direction D2 of the insulating structure DW.

The insulating structure DW may include a low dielectric constant material. For example, the insulating structure DW may include at least one of silicon nitride (SiN), silicon carbonitride (SiCN), silicon oxynitride (SiON), silicon oxycarbonitride (SiOCN), and a low dielectric constant material, but the present disclosure is not limited thereto.

As described above, the insulating structure DW of the semiconductor device according to the present disclosure may effectively perform electrical isolation between the first device region RX1 and the second device region RX2 by including an insulating material.

As described above, the insulating structure DW of the semiconductor device according to the present disclosure may improve a degree of integration of the device by contacting the first channel pattern CP1 and the second channel pattern CP2.

The semiconductor device according to the embodiment may further include the gate spacer 140 and a capping layer 145.

According to an embodiment, the gate spacer 140 may be disposed at both sides of the main gate electrode 120M. Although the gate spacer 140 is shown as a single film in the drawings, this is only for ease of description, and the present disclosure is not limited thereto.

For example, the gate spacer 140 may include at least one of silicon nitride (SiN), silicon oxynitride (SiON), silicon oxide (SiO₂), silicon oxycarbonitride (SiOCN), silicon boronnitride (SiBN), silicon oxyboron nitride (SiOBN), silicon carbonate (SiOC), and a combination thereof. Although the gate spacer 140 is shown as a single film in the drawings, this is only for ease of description, and the present disclosure is not limited thereto.

According to an embodiment, the capping layer 145 may be disposed on the main gate structure M_GS and the gate spacer 140. An upper surface of the capping layer 145 may be disposed on the same plane as that of an upper surface of the first interlayer insulating layer 160. Unlike the illustration in the drawings, the capping layer 145 may be disposed between gate spacers 140. Alternatively, unlike the illustration in the drawings, the capping layer 145 may be omitted.

For example, the capping layer 145 may include at least one of silicon nitride (SiN), silicon oxynitride (SiON), silicon carbonitride (SiCN), silicon oxycarbonitride (SiOCN), and a combination thereof. The capping layer 145 may include a material having etch selectivity with respect to the first interlayer insulating layer 160.

Referring to FIG. 5 and FIG. 6, the first device region RX1 and the second device region RX2 may include the source/drain patterns 150 disposed on the substrate 110. According to an embodiment, the source/drain patterns 150 may be disposed to be spaced apart along the first direction D1 on the substrate 110. Although not clearly illustrated in the drawings, the source/drain patterns 150 may also be disposed in the second direction D2.

Referring to FIG. 5, in the first device region RX1, the first channel pattern CP1 and the gate structure GS may be disposed between the source/drain patterns 150. In other words, in the first device region RX1, a plurality of source/drain patterns 150 and the plurality of first channel patterns CP1 may be alternately disposed along the first direction D1.

According to an embodiment, in the first device region RX1, the source/drain pattern 150 may be disposed at both sides of the multiple sub-channel patterns of the first channel pattern CP1 and/or the sub-gate structure S_GS. For example, two source/drain patterns 150 may be disposed to be spaced apart in a direction (e.g., the first direction D1) intersecting a direction in which the gate structure GS extends with the first channel patterns CP1 and/or the sub-gate structure S_GS interposed therebetween. An upper surface of the source/drain pattern 150 may be disposed at substantially the same level as that of an upper surface of the first channel pattern CP1 disposed at an uppermost portion among the first channel patterns CP1, but the present disclosure is not limited thereto. The source/drain pattern 150 may be in direct contact with the first channel pattern CP1 and the sub-gate structure S_GS.

Referring to FIG. 6, in the second device region RX2, the second channel pattern CP2 and the gate structure GS may be disposed between the source/drain patterns 150. In other words, in the second device region RX2, the plurality of source/drain patterns 150 and the plurality of second channel patterns CP2 may be alternately disposed along the first direction D1.

According to an embodiment, in the second device region RX2, the source/drain pattern 150 may be disposed at both sides of the multiple sub-channel patterns of the second channel pattern CP2 and/or the sub-gate structure S_GS. For example, two source/drain patterns 150 may be disposed to be spaced apart in a direction (e.g., the first direction D1) intersecting a direction in which the gate structure GS extends with the second channel patterns CP2 and/or the sub-gate structure S_GS interposed therebetween. The upper surface of the source/drain pattern 150 may be disposed at substantially the same level as that of an upper surface of the second channel pattern CP2 disposed at an uppermost portion among the second channel patterns CP2, but the present disclosure is not limited thereto. The source/drain pattern 150 may be in direct contact with the second channel pattern CP2 and the sub-gate structure S_GS.

According to an embodiment, a side surface of the source/drain pattern 150 may have an uneven embossed shape. In other words, the side surface of the source/drain pattern 150 may have a wavy profile. For example, a side surface of the source/drain pattern 150 adjacent to the sub-gate structure S_GS may have an approximately convex shape toward the sub-gate structure S_GS, and a side surface of the source/drain pattern 150 adjacent to the first channel patterns CP1 may have an approximately concave shape toward the first channel patterns CP1.

According to an embodiment, the source/drain pattern 150 may include an epitaxial region of a semiconductor material. For example, the source/drain pattern 150 may include a semiconductor element (e.g., Si or SiGe). The source/drain pattern 150 may serve as a source/drain of a transistor that uses the first and second channel patterns CP1 and CP2 as a channel region.

According to an embodiment, the source/drain pattern 150 may include a first source/drain layer 150a and a second source/drain layer 150b. The first source/drain layer 150a may have a shape that surrounds a side surface and a lower surface of the second source/drain layer 150b.

The first and second channel patterns CP1 and CP2 may be in contact with the first source/drain layer 150a, and may not be in contact with the second source/drain layer 150b. Therefore, the first source/drain layer 150a may be disposed between the first and second channel patterns CP1 and CP2 and the second source/drain layer 150b.

According to an embodiment, a lower surface of the first source/drain layer 150a may be disposed at a level similar to or the same as that of a lower surface of the sub-gate structure S_GS disposed at a lowermost portion among the sub-gate structures S_GS.

According to an embodiment, the source/drain pattern 150 may include or may be doped with a P-type impurity (or a P-type dopant) or an N-type impurity (or an N-type dopant).

According to an embodiment, the source/drain pattern 150 disposed at the first device region RX1 may include a P-type impurity. For example, the source/drain pattern 150 disposed at the first device region RX1 may include B, V, In, Ga, Al, or a combination thereof.

According to an embodiment, the source/drain pattern 150 disposed at the second device region RX2 may include an N-type impurity. For example, the source/drain pattern 150 disposed at the second device region RX2 may include P, Sb, As, or a combination thereof.

The semiconductor device according to the embodiment may further include the gate separation structure CT penetrating the gate electrode 120. According to an embodiment, the gate separation structure CT may penetrate the gate electrode 120 in the third direction D3. As shown in FIG. 3 and FIG. 4, a lower surface of the gate separation structure CT may be disposed at a similar level to that of a lower surface of the insulating structure DW. However, the present disclosure is not limited thereto, and a lower level of the gate separation structure CT may be variously changed. According to an embodiment, an upper surface of the gate separation structure CT may be disposed at substantially the same level as that of an upper surface of the insulating structure DW. However, the present disclosure is not limited thereto, and an upper level of the gate separation structure CT may be variously changed.

According to an embodiment, the gate separation structure CT may cut and separate the gate electrode 120 extending in the second direction D2 to be spaced apart from each other with respect to the gate separation structure CT. For example, the gate separation structure CT may be made of silicon nitride.

According to an embodiment, the gate separation structure CT may be disposed adjacent to one side of the first device region RX1 and/or one side of the second device region RX2. For example, the gate separation structure CT may be disposed adjacent to the one side (e.g., an upper side) of the first device region RX1. For example, the gate separation structure CT may face the insulating structure DW with the first channel pattern CP1 interposed therebetween.

For example, the gate separation structure CT may be disposed adjacent to the one side (e.g., a lower side) of the second device region RX2. For example, the gate separation structure CT may face the insulating structure DW with the second channel pattern CP2 interposed therebetween.

As shown in FIG. 5, according to an embodiment, the device separation film SDB may be disposed at one side of the first device region RX1. According to an embodiment, the device separation film SDB may not be disposed at the other side of the first device region RX1. Although FIG. 5 illustrates that the device separation film SDB is disposed at the right side of the first device region RX1 and the device separation film SDB is not disposed at the left side thereof, the present disclosure is not limited thereto, and the device separation film SDB may be disposed at the left side of the first device region RX1 and the device separation film SDB may not be disposed at the right side thereof.

According to an embodiment, the device separation film SDB may penetrate the gate structure GS disposed at one edge of the first device region RX1. According to an embodiment, an upper surface of the device separation film SDB may be disposed at substantially the same level as that of an upper surface of the capping layer 145. According to an embodiment, the device separation film SDB may physically separate the first device region RX1 from a region of another cell adjacent to the first device region RX1.

For example, the device separation film SDB may include at least one of silicon oxide (SiO₂), silicon nitride (SiN), silicon oxynitride (SiON), and a low dielectric constant material.

The semiconductor device according to the embodiment may further include the first interlayer insulating layer 160 and a second interlayer insulating layer 170. The first interlayer insulating layer 160 may be disposed on a side surface of the gate spacer 140, a side surface of the capping layer 145, and an upper surface of the source/drain pattern 150. An upper surface of the first interlayer insulating layer 160 may be disposed at substantially the same level as that of the upper surface of the device separation film SDB.

According to an embodiment, the second interlayer insulating layer 170 covering the capping layer 145 may be disposed on the first interlayer insulating layer 160 and the device separation film SDB. A boundary between the second interlayer insulating layer 170 and the first interlayer insulating layer 160 and/or the device separation film SDB may not be recognized.

For example, the first interlayer insulating layer 160 may include at least one of silicon oxide (SiO₂), silicon nitride (SiN), silicon oxynitride (SiON), and a low dielectric constant material. For example, the low dielectric constant material may include Fluorinated TetraEthylOrthoSilicate (FTEOS), Hydrogen SilsesQuioxane (HSQ), Fluoride Silicate Glass (FSG), polyimide nanofoams such as polypropylene oxide, Carbon Doped silicon Oxide (CDO), Organo-Silicate Glass (OSG), SILK, amorphous fluorinated carbon, silica aerogels, silica xerogels, mesoporous silica, or a combination thereof, but the present disclosure is not limited thereto.

According to an embodiment, the second interlayer insulating layer 170 may include the same material as that of the first interlayer insulating layer 160. For example, the second interlayer insulating layer 170 may include at least one of silicon oxide (SiO₂), silicon nitride (SiN), silicon oxynitride (SiON), and a low dielectric constant material.

The semiconductor device according to the embodiment may further include the contact pattern CA disposed on at least one of the source/drain patterns 150, an upper insulating layer 180 disposed on the second interlayer insulating layer 170, and the upper wire M1.

According to an embodiment, the contact pattern CA may penetrate the first interlayer insulating layer 160 to be connected to at least one of the source/drain patterns 150. According to an embodiment, the contact pattern CA may be disposed adjacent to the main gate electrode 120M in the first direction D1. According to an embodiment, the contact pattern CA may electrically connect the upper wire M1 to at least one of the source/drain patterns 150 through the contact via CAV. However, the present disclosure is not limited thereto, and in some embodiments, the contact via CAV may be omitted.

For example, the contact pattern CA may include at least one of a metal, a metal alloy, conductive metal nitride, conductive metal carbide, conductive metal oxide, conductive metal carbonitride, and a two-dimensional (2D) material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CON), and platinum nitride (PtN).

According to an embodiment, the upper insulating layer 180, the upper wire M1, and upper vias (not shown) may be disposed above or on the second interlayer insulating layer 170. Upper wires M1 and the upper vias may include a metal (e.g., copper). The upper insulating layer 180 may be disposed between the upper wires M1 and the upper vias to insulate the upper wires M1 and the upper vias. The upper insulating layer 180 may cover the second interlayer insulating layer 170. The upper wires M1 and the upper vias may be disposed within the upper insulating layer 180.

According to an embodiment, the upper insulating layer 180 may include at least one of silicon oxide (SiOx), silicon nitride (SiNx), silicon oxynitride (SiON), and low dielectric films.

According to an embodiment, the upper wire M1 may be electrically connected to at least one of the main gate electrode 120M and the source/drain pattern 150. According to an embodiment, an electrical signal or a power source voltage supplied from the outside may be provided to the source/drain patterns 150 through the upper wire M1 and the contact pattern CA connected to the upper wire M1.

The semiconductor device according to the embodiment may further include the lower contact pattern BCA disposed below at least one of the source/drain patterns 150 and the lower wire BM1 disposed on a lower surface of the substrate 110.

According to an embodiment, the lower contact pattern BCA may be electrically connected to at least one of the source/drain patterns 150. According to an embodiment, the lower contact pattern BCA may electrically connect the lower wire BM1 to at least one of the source/drain patterns 150. According to an embodiment, the lower contact pattern BCA may electrically connect the lower wire BM1 to at least one of the source/drain patterns 150 through the lower via BVA.

For example, the lower contact pattern BCA may include at least one of a metal, a metal alloy, conductive metal nitride, conductive metal carbide, conductive metal oxide, conductive metal carbonitride, and a two-dimensional (2D) material. The metal may include at least one of titanium (Ti), tantalum (Ta), tungsten (W), nickel (Ni), cobalt (Co), and platinum (Pt). The conductive metal nitride may include at least one of titanium nitride (TiN), tantalum nitride (TaN), tungsten nitride (WN), nickel nitride (NiN), cobalt nitride (CON), and platinum nitride (PtN).

According to an embodiment, the lower wire BM1 and lower vias BVA may be disposed within the substrate 110 formed of an insulating material. Lower wires BM1 and the lower vias BVA may include a metal (e.g., copper). The substrate 110 including an insulating material may be disposed between the lower wire BM1 and the lower vias BVA to insulate the lower wire BM1 and the lower vias BVA.

According to an embodiment, the lower wire BM1 may be electrically connected to at least one of the gate electrode 120 and the source/drain pattern 150. According to an embodiment, an electrical signal or a power source voltage supplied from the outside may be provided to the source/drain patterns 150 through the lower wire BM1 and the lower contact pattern BCA connected to the lower wire BM1. According to an embodiment, an electrical signal or a power source voltage supplied from the outside may be provided to the gate electrode 120 through the lower wire BM1 and the lower gate pattern BCB connected to the lower wire BM1.

According to an embodiment, the same level of voltage may be provided to the source/drain patterns 150 and the sub-gate electrode 120S through the lower contact pattern BCA and the lower gate pattern BCB, respectively. Accordingly, no potential difference may occur between the gate electrode 120 and the source/drain pattern 150, so that an electric current flow between a source and a drain is blocked. Thus, the source and the drain may be electrically separated. In other words, the lower gate pattern BCB may electrically separate the first device region RX1 and/or the second device region RX2 from a region of another cell adjacent to the first device region RX1 and/or the second device region RX2 using the lower gate pattern BCB as a boundary.

According to an embodiment, the lower wire BM1 may be connected to the gate structure GS disposed at one edge of the first device region RX1 and/or the second device region RX2. Referring to FIG. 3 and FIG. 5, in the first device region RX1, the lower wire BM1 may be connected to the gate structure GS disposed at one edge of the first device region RX1. According to an embodiment, a first lower gate pattern BCB1 disposed at one edge of the first device region RX1 may electrically separate the first device region RX1 from a region of another cell region adjacent to the first device region RX1 using the first lower gate pattern BCB1 as a boundary. Accordingly, the first device region RX1 may be defined by disposing the device separation film SDB for physically separating the first device region RX1 from a region of another cell adjacent to the first device region RX1 at one edge of the first device region RX1 and including the first lower gate pattern BCB1 for electrically separating the first device region RX1 from a region of another cell adjacent to the first device region RX1 at the other edge of the first device region RX1.

Referring to FIG. 4 and FIG. 6, in the second device region RX2, the lower wire BM1 may be connected to the gate structures GS disposed at both edges of the second device region RX2. According to an embodiment, a second lower gate pattern BCB2 may be disposed between the lower wire BM1 and the gate structure GS. According to an embodiment, the second lower gate pattern BCB2 disposed at both edges of the second device region RX2 may electrically separate the second device region RX2 from a region of another cell adjacent to the second device region RX2 using the second lower gate pattern BCB2 as a boundary. Accordingly, the second device region RX2 may be defined by including the second lower gate pattern BCB2 for electrically separating the second device region RX2 from a region of another cell adjacent to the second device region RX2 at both edges of the second device region RX2.

Referring to FIG. 3 and FIG. 4, in the first device region RX1, the gate structure GS disposed at one edge of the first device region RX1 may be connected to a first lower wire BM1(VDD) to which a first voltage is applied. For example, in the first device region RX1, the gate structure GS disposed at the one edge of the first device region RX1 may be connected to the first lower wire BM1(VDD) to which the first voltage is applied through the first lower gate pattern BCB1.

Referring to FIG. 3 and FIG. 4, in the second device region RX2, the gate structure GS disposed at both edges of the second device region RX2 may be connected to the second lower wire BM1(VSS) to which a second voltage lower than the first voltage is applied. For example, in the second device region RX2, the gate structure GS disposed at both edges of the second device region RX2 may be connected to the second lower wire BM1(VSS) to which the second voltage is applied through the second lower gate pattern BCB2.

As described above, the semiconductor device according to the present disclosure may effectively prevent leakage of an electric current by mixing and using diffusion breaks within at least one device region according to the characteristics of the first device region RX1 and the second device region RX2 including or doped with different types of dopants.

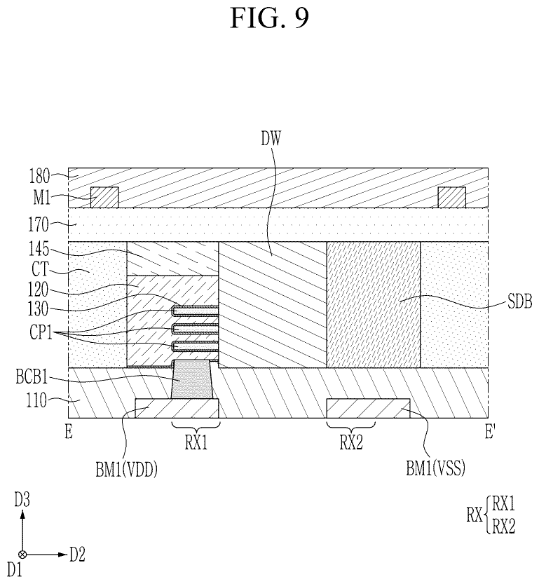

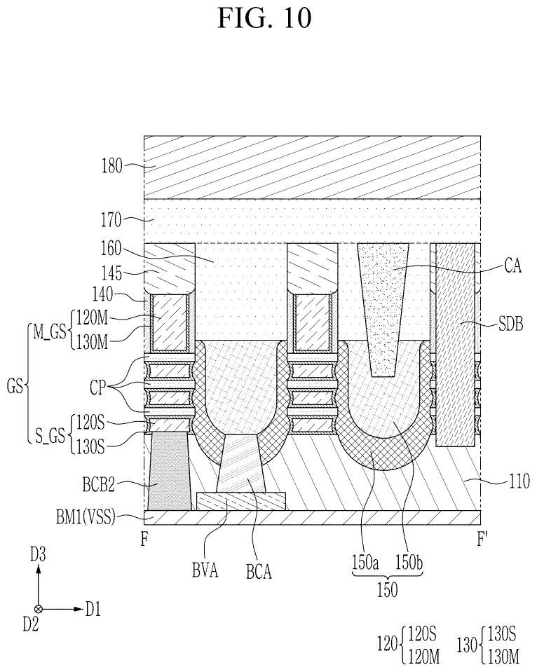

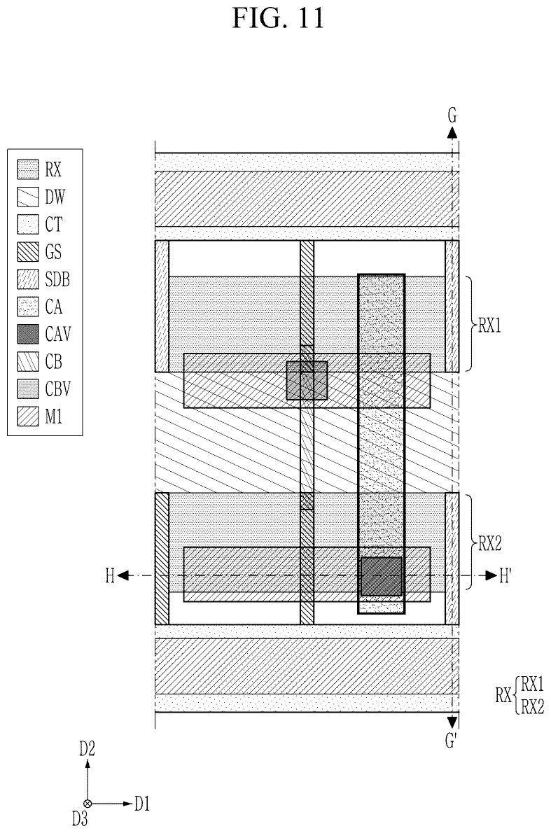

Each of FIG. 7 and FIG. 8 is a layout diagram showing a semiconductor device according to an embodiment of the present disclosure. FIG. 9 is a cross-sectional view of the semiconductor device along line E-E′ of each of FIG. 7 and FIG. 8. FIG. 10 is a cross-sectional view of the semiconductor device along line F-F′ of each of FIG. 7 and FIG. 8.

The semiconductor device illustrated in FIGS. 7 to 10 may include a component similar to or the same as that of the semiconductor device described with reference to FIGS. 1 to 6. However, unlike the semiconductor device illustrated in FIGS. 1 to 6, the semiconductor device of the present embodiment relates to a structure in which a lower wire BM1 connected to a gate structure GS disposed at both edges of a first device region RX1 is disposed at the first device region RX1 included in a unit cell of the semiconductor device and both the lower wire BM1 connected to the gate structure GS disposed at one edge of the second device region RX2 and a device separation film SDB penetrating the gate structure GS disposed at the other edge of the second device region RX2 are disposed. Contents of the present embodiment overlapping the contents described with reference to FIGS. 1 to 6 will be simplified or omitted, and a difference between the contents of the present embodiment and the contents described with reference to FIGS. 1 to 6 will be mainly described.

Referring to FIGS. 7 to 10, one unit cell of the semiconductor device according to the embodiment may include the first device region RX1 where a first channel pattern CP1 is disposed, the second device region RX2 where a second channel pattern CP2 is disposed, and an insulating structure DW separating the first device region RX1 from the second device region RX2. According to an embodiment, the insulating structure DW may extend in the first direction D1 between the first device region RX1 and the second device region RX2.

According to an embodiment, the insulating structure DW may be in contact with the first channel pattern CP1 and the second channel pattern CP2 in the second direction D2. In other words, the insulating structure DW may not be spaced apart from the first channel pattern CP1 and the second channel pattern CP2 in the second direction D2.

As described above, the insulating structure DW of the semiconductor device according to the present disclosure may improve a degree of integration of the device by contacting the first channel pattern CP1 and the second channel pattern CP2.

According to an embodiment, one unit cell of the semiconductor device may include the device separation film SDB that physically separates adjacent cells and/or a lower gate pattern BCB that electrically separates adjacent cells.

Referring to FIG. 7 and FIG. 8, in the first device region RX1, the lower wire BM1 may be connected to the gate structure GS disposed at both edges of the first device region RX1. According to an embodiment, a first lower gate pattern BCB1 disposed at both edges of the first device region RX1 may electrically separate the first device region RX1 from a region of another cell region adjacent to the first device region RX1 using the first lower gate pattern BCB1 as a boundary.

Referring to FIG. 9, the gate structure GS included in the first device region RX1 may be connected to a first lower wire BM1(VDD) to which a first voltage is applied. For example, the gate structure GS of the first device region RX1 may be connected to the first lower wire BM1(VDD) to which the first voltage is applied through the first lower gate pattern BCB1. The first voltage may be a positive voltage.

According to an embodiment, the device separation film SDB may be disposed at one side of the second device region RX2. According to an embodiment, the device separation film SDB may not be disposed at the other side of the second device region RX2. Although FIG. 7, FIG. 8, and FIG. 10 illustrate that the device separation film SDB is disposed at a right side of the second device region RX2 and the device separation film SDB is not disposed at a left side of the second device region RX2, the present disclosure is not limited thereto, and the device separation film SDB may be disposed at the left side of the second device region RX2 and the device separation film SDB may not be disposed at the right side thereof.

According to an embodiment, the device separation film SDB may penetrate the gate structure GS disposed at one edge of the second device region RX2. According to an embodiment, the device separation film SDB may physically separate the second device region RX2 from a region of another cell adjacent to the second device region RX2.

According to an embodiment, in the second device region RX2, the lower wire BM1 may be connected to the gate structure GS disposed at the other edge of the second device region RX2. According to an embodiment, a second lower gate pattern BCB2 disposed at the other edge of the second device region RX2 may electrically separate the second device region RX2 from a region of another cell region adjacent to the second device region RX2 using the second lower gate pattern BCB2 as a boundary. In other words, one side of the second device region RX2 may be physically terminated by the device separation film SDB that is a boundary, and the other side of the second device region RX2 may be electrically terminated by the second lower gate pattern BCB2 that is a boundary.

Although not clearly illustrated in the drawings, the gate structure GS disposed at the other edge of the second device region RX2 may be connected to a second lower wire BM1(VSS) to which a second voltage is applied. For example, the gate structure GS of the second device region RX2 may be connected to the second lower wire BM1(VSS) to which the second voltage is applied through the second lower gate pattern BCB2. The second voltage may be a negative voltage or a ground voltage.

As described above, the semiconductor device of the present embodiment may include the first lower gate pattern BCB1 connected to the lower wire BM1 at both sides of the first device region RX1, the device separation film SDB disposed at one side of the second device region RX2, and the second lower gate pattern BCB2 disposed at the other side of the second device region RX2, so that leakage of an electric current according to a characteristic of the device is effectively prevented.

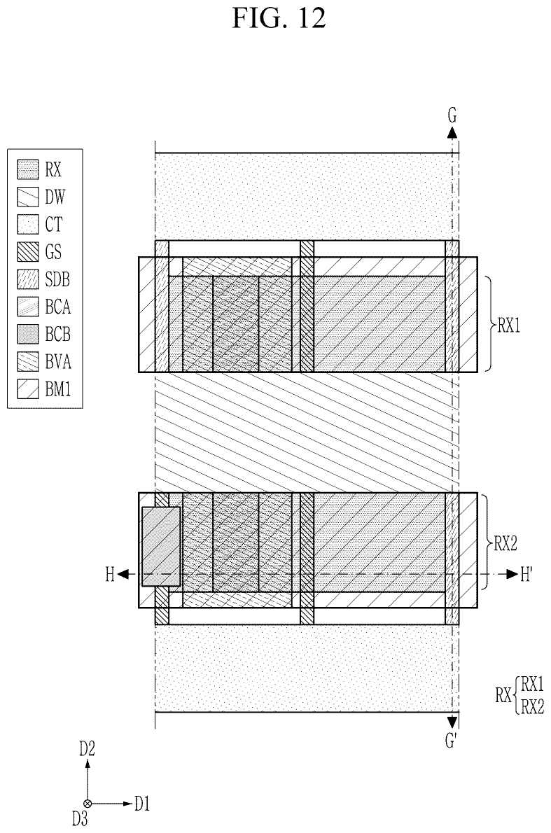

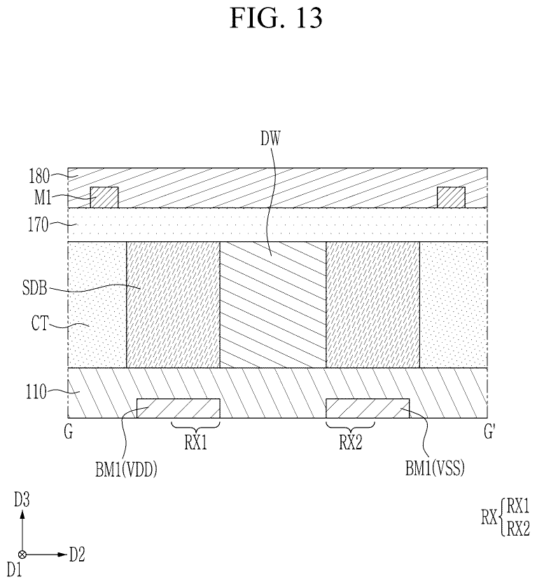

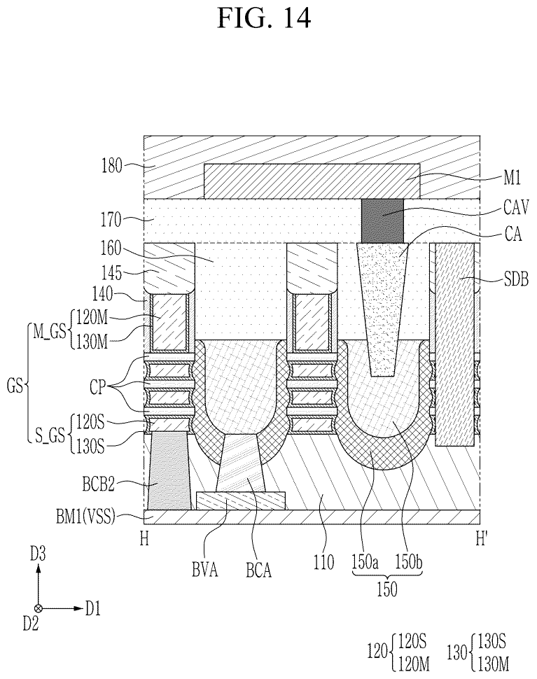

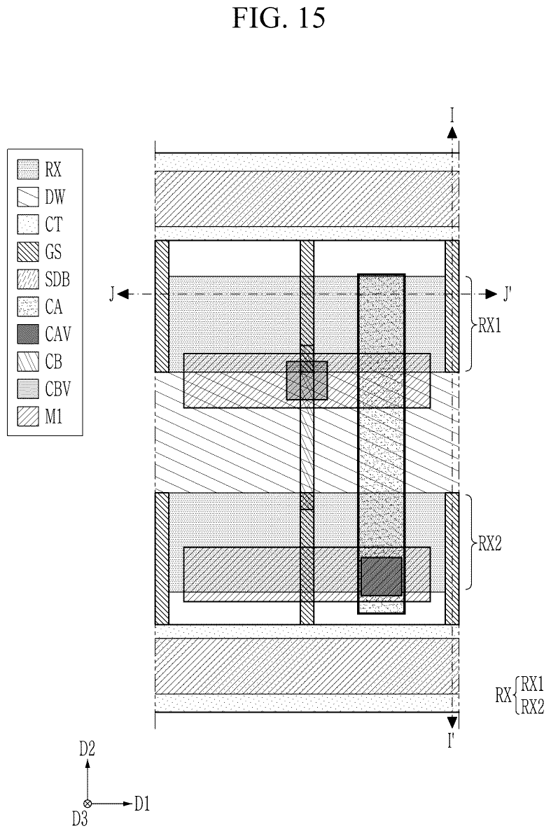

Each of FIG. 11 and FIG. 12 is a layout diagram showing a semiconductor device according to an embodiment of the present disclosure. FIG. 13 is a cross-sectional view of the semiconductor device along line G-G′ of each of FIG. 11 and FIG. 12. FIG. 14 is a cross-sectional view of the semiconductor device along line H-H′ of each of FIG. 11 and FIG. 12.

The semiconductor device illustrated in FIGS. 11 to 14 may include a component similar to or the same as that of the semiconductor device described with reference to FIGS. 1 to 6. However, unlike the semiconductor device illustrated in FIGS. 1 to 6, the semiconductor device of the present embodiment relates to a structure in which a device separation film SDB penetrating a gate structure GS disposed at both edges of a first device region RX1 is disposed at the first device region RX1 included in a unit cell of the semiconductor device and both a lower wire BM1 connected to the gate structure GS disposed at one edge of the second device region RX2 and the device separation film SDB penetrating the gate structure GS disposed at the other edge of the second device region RX2 are disposed. Contents of the present embodiment overlapping the contents described with reference to FIGS. 1 to 6 will be simplified or omitted, and a difference between the contents of the present embodiment and the contents described with reference to FIGS. 1 to 6 will be mainly described.

Referring to FIGS. 11 to 14, one unit cell of the semiconductor device according to the embodiment may include the first device region RX1 where a first channel pattern CP1 is disposed, the second device region RX2 where a second channel pattern CP2 is disposed, and an insulating structure DW separating the first device region RX1 from the second device region RX2. According to an embodiment, the insulating structure DW may extend in the first direction D1 between the first device region RX1 and the second device region RX2.

According to an embodiment, the insulating structure DW may be in contact with the first channel pattern CP1 and the second channel pattern CP2 in the second direction D2. In other words, the insulating structure DW may not be spaced apart from the first channel pattern CP1 and the second channel pattern CP2 in the According to an embodiment, one unit cell of the semiconductor device may include the device separation film SDB that physically separates adjacent cells and/or a lower gate pattern BCB that electrically separates adjacent cells.

Referring to FIG. 11 and FIG. 12, the first device region RX1 may include the device separation film SDB penetrating the gate structure GS disposed at both edges of the first device region RX1. According to an embodiment, the device separation film SDB disposed at both edges of the first device region RX1 may physically separate the first device region RX1 from a region of another cell adjacent to the first device region RX1 using the device separation film SDB as a boundary. In other words, both sides of the first device region RX1 may be physically terminated by the device separation film SDB that is a boundary.

According to an embodiment, the device separation film SDB may be disposed at one side of the second device region RX2. According to an embodiment, the device separation film SDB may not be disposed at the other side of the second device region RX2. Although FIG. 11, FIG. 12, and FIG. 14 illustrate that the device separation film SDB is disposed at a right side of the second device region RX2 and the device separation film SDB is not disposed at a left side of the second device region RX2, the present disclosure is not limited thereto, and the device separation film SDB may be disposed at the left side of the second device region RX2 and the device separation film SDB may not be disposed at the right side thereof.

According to an embodiment, the device separation film SDB may penetrate the gate structure GS disposed at one edge of the second device region RX2. According to an embodiment, the device separation film SDB may physically separate the second device region RX2 from a region of another cell adjacent to the second device region RX2.

According to an embodiment, in the second device region RX2, the lower wire BM1 may be connected to the gate structure GS disposed at the other edge of the second device region RX2. According to an embodiment, a second lower gate pattern BCB2 disposed at the other edge of the second device region RX2 may electrically separate the second device region RX2 from a region of another cell region adjacent to the second device region RX2 using the second lower gate pattern BCB2 as a boundary. In other words, one side of the second device region RX2 may be physically terminated by the device separation film SDB that is a boundary, and the other side of the second device region RX2 may be electrically terminated by the second lower gate pattern BCB2 that is a boundary.

Although not clearly illustrated in the drawings, the gate structure GS disposed at the other edge of the second device region RX2 may be connected to a second lower wire BM1(VSS) to which a second voltage is applied. For example, the gate structure GS of the second device region RX2 may be connected to the second lower wire BM1(VSS) to which the second voltage is applied through the second lower gate pattern BCB2. The second voltage may be a negative voltage or a ground voltage.

As described above, the semiconductor device of the present embodiment may include the device separation film SDB at both sides of the first device region RX1, the device separation film SDB disposed at one side of the second device region RX2, and the second lower gate pattern BCB2 disposed at the other side of the second device region RX2, so that leakage of an electric current according to a characteristic of the device is effectively prevented.

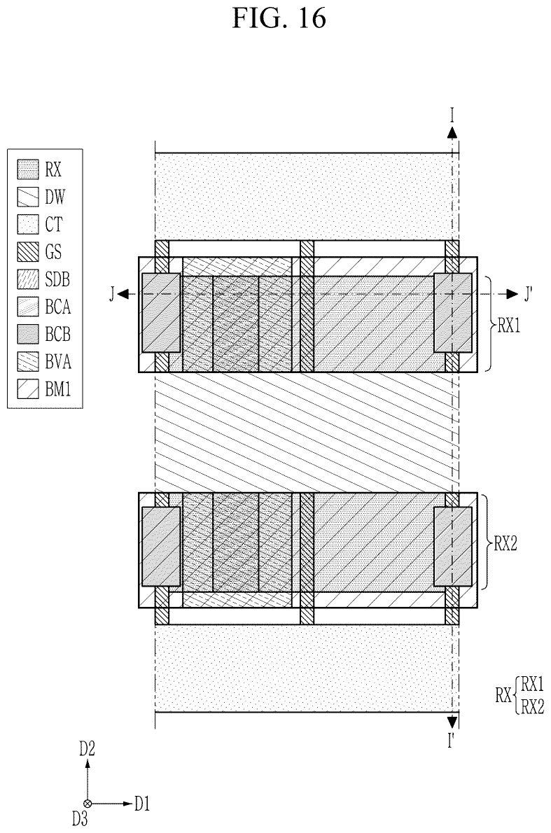

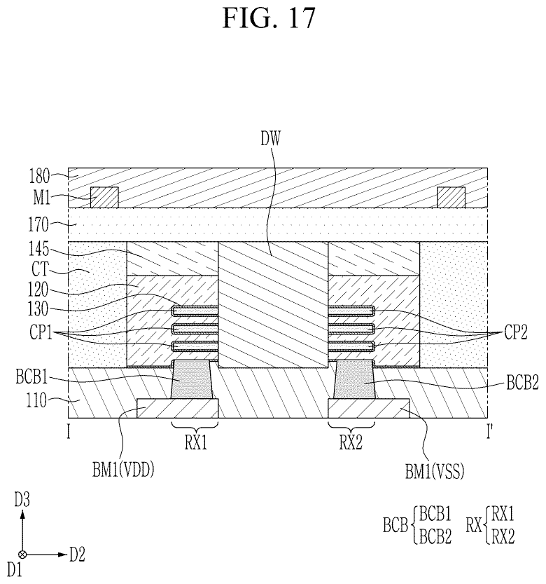

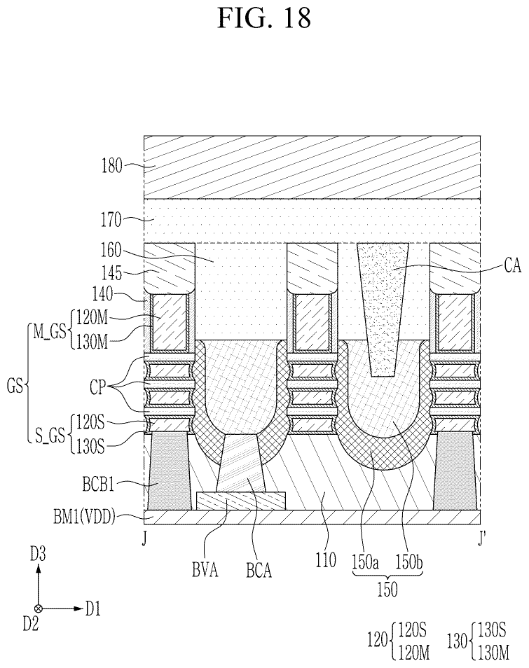

Each of FIG. 15 and FIG. 16 is a layout diagram showing a semiconductor device according to an embodiment of the present disclosure. FIG. 17 is a cross-sectional view of the semiconductor device along line I-I′ of each of FIG. 15 and FIG. 16. FIG. 18 is a cross-sectional view of the semiconductor device along line J-J′ of each of FIG. 15 and FIG. 16.

The semiconductor device illustrated in FIGS. 15 to 18 may include a component similar to or the same as that of the semiconductor device described with reference to FIGS. 1 to 6. However, unlike the semiconductor device illustrated in FIGS. 1 to 6, the semiconductor device of the present embodiment relates to a structure in which a lower wire BM1 connected to a gate structure GS disposed at both edges of each of a first device region RX1 and a second device region RX2 is disposed at each of the first device region RX1 and the second device region RX2 included in a unit cell of the semiconductor device. Contents of the present embodiment overlapping the contents described with reference to FIGS. 1 to 6 will be simplified or omitted, and a difference between the contents of the present embodiment and the contents described with reference to FIGS. 1 to 6 will be mainly described.

Referring to FIGS. 15 to 18, one unit cell of the semiconductor device according to the embodiment may include the first device region RX1 where a first channel pattern CP1 is disposed, the second device region RX2 where a second channel pattern CP2 is disposed, and an insulating structure DW separating the first device region RX1 from the second device region RX2. According to an embodiment, the insulating structure DW may extend in the first direction D1 between the first device region RX1 and the second device region RX2.

According to an embodiment, the insulating structure DW may be in contact with the first channel pattern CP1 and the second channel pattern CP2 in the second direction D2. In other words, the insulating structure DW may not be spaced apart from the first channel pattern CP1 and the second channel pattern CP2 in the second direction D2.

According to an embodiment, one unit cell of the semiconductor device may include a lower gate pattern BCB that electrically separates adjacent cells.

Referring to FIG. 15 and FIG. 16, in the first and second device regions RX1 and RX2, the lower wire BM1 may be connected to the gate structure GS disposed at both edges of each of the first and second device regions RX1 and RX2.

According to an embodiment, a first lower gate pattern BCB1 disposed at both edges of the first device region RX1 may electrically separate the first device region RX1 from a region of another cell region adjacent to the first device region RX1 using the first lower gate pattern BCB1 as a boundary.

According to an embodiment, a second lower gate pattern BCB2 disposed at both edges of the second device region RX2 may electrically separate the second device region RX2 from a region of another cell adjacent to the second device region RX2 using the second lower gate pattern BCB2 as a boundary.

Referring to FIG. 17, the gate structure GS disposed at an edge of the first device region RX1 may be connected to a first lower wire BM1(VDD) to which a first voltage is applied. For example, the gate structure GS of the first device region RX1 may be connected to the first lower wire BM1(VDD) to which the first voltage is applied through the first lower gate pattern BCB1. The first voltage may be a positive voltage. According to an embodiment, the gate structure GS disposed at an edge of the second device region RX2 may be connected to a second lower wire BM1(VSS) to which a second voltage is applied. For example, the gate structure GS of the second device region RX2 may be connected to the second lower wire BM1(VSS) to which the second voltage is applied through the second lower gate pattern BCB2. The second voltage may be a negative voltage or a ground voltage.

As described above, the semiconductor device of the present embodiment may prevent leakage of an electric current by including the lower gate pattern BCB at both sides of each of the first and second device regions RX1 and RX2.

As described above, the semiconductor device of the present embodiment may include the insulating structure DW in contact with the first and second channel patterns CP1 and CP2 between the first device region RX1 and the second device region RX2, so that it is possible to physically and/or electrically separate the first device region RX1 and the second device region RX2 while increasing a degree of integration of the device.

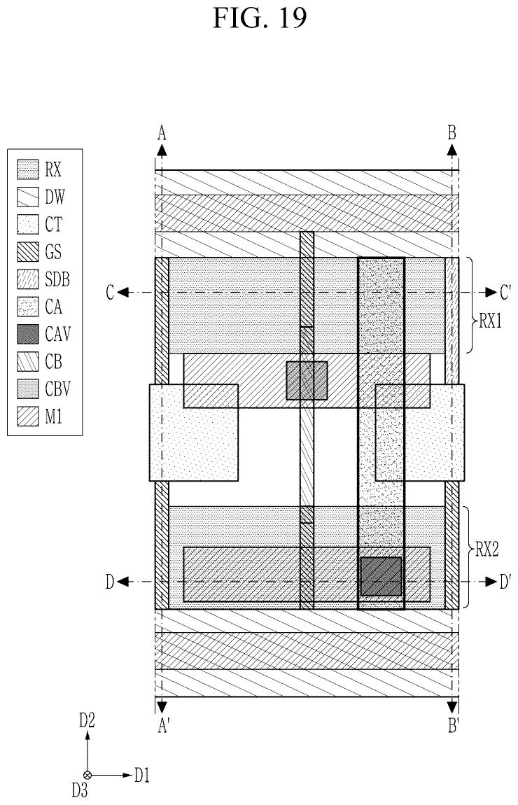

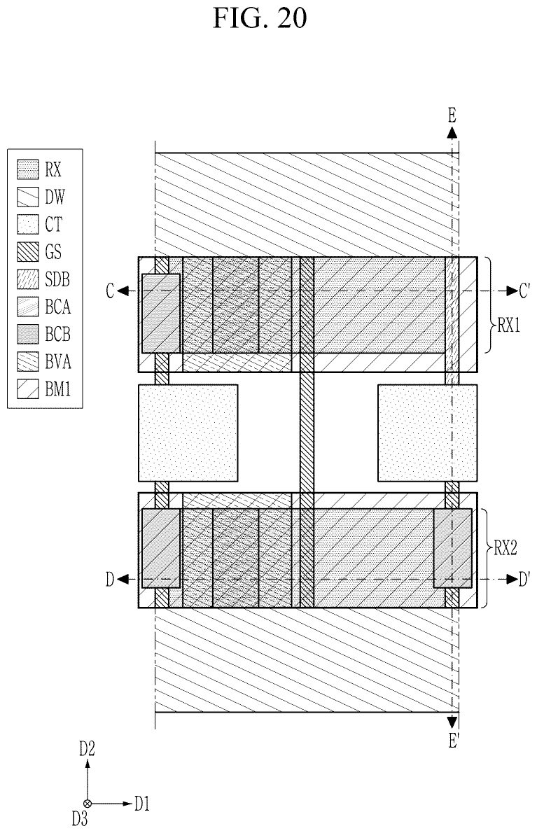

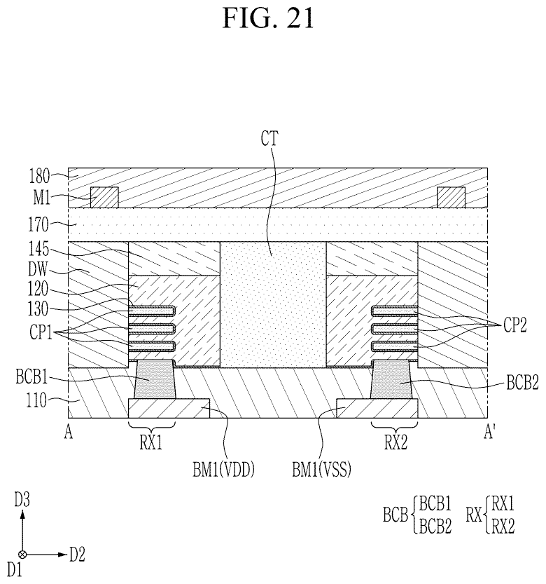

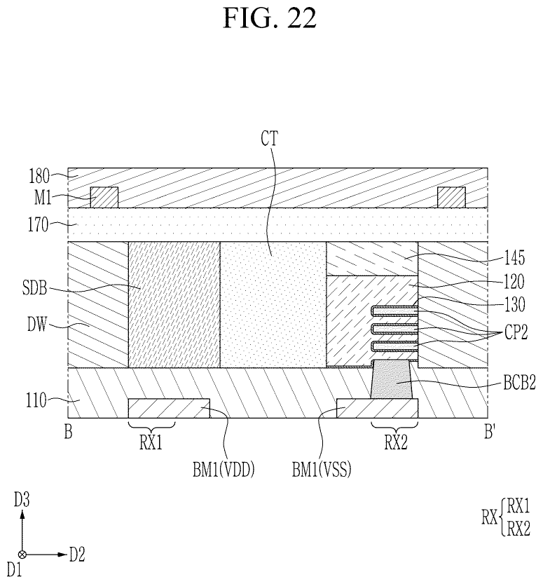

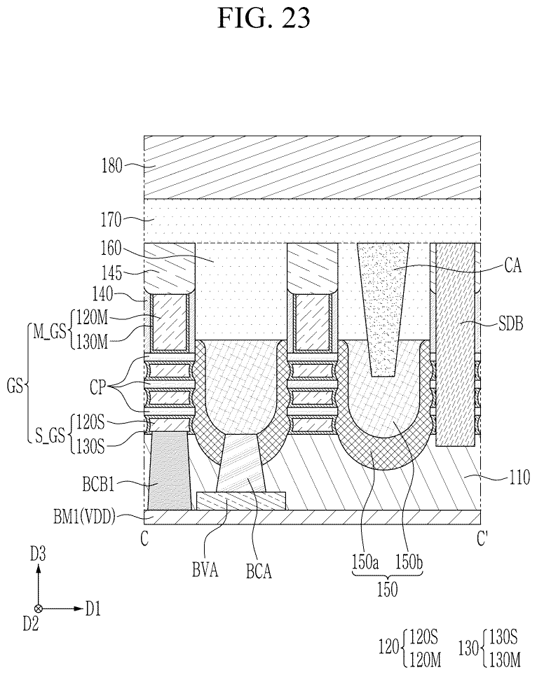

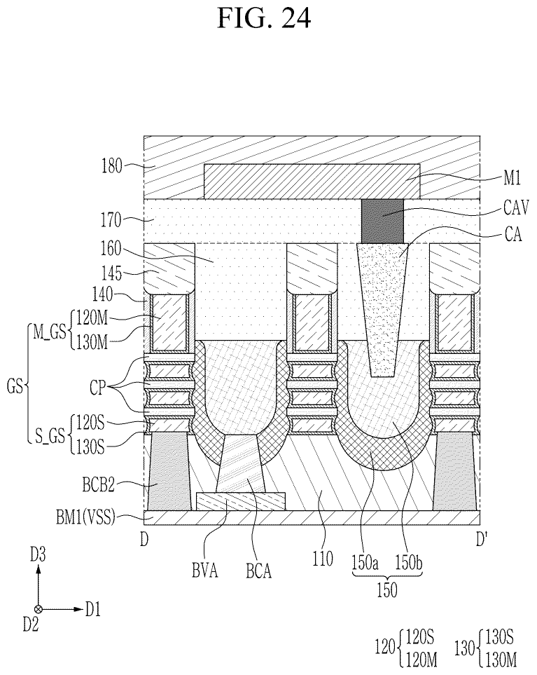

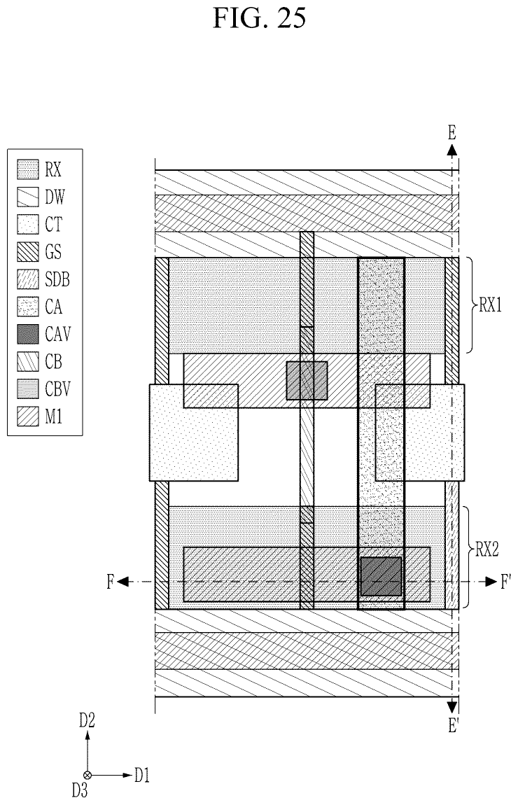

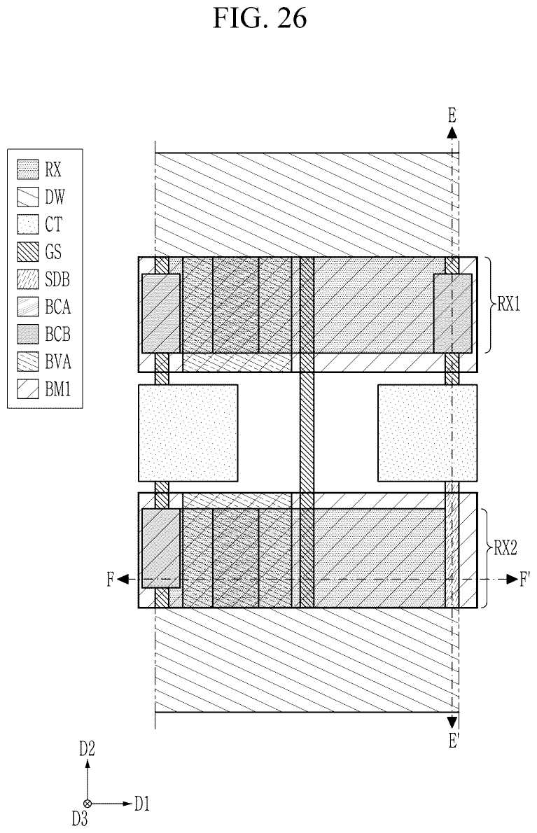

Each of FIG. 19 and FIG. 20 is a layout diagram showing a semiconductor device according to an embodiment of the present disclosure. FIG. 21 is a cross-sectional view of the semiconductor device along line A-A′ of each of FIG. 19 and FIG. 20. FIG. 22 is a cross-sectional view of the semiconductor device along line B-B′ of each of FIG. 19 and FIG. 20. FIG. 23 is a cross-sectional view of the semiconductor device along line C-C′ of each of FIG. 19 and FIG. 20. FIG. 24 is a cross-sectional view of the semiconductor device along line D-D′ of each of FIG. 19 and FIG. 20.

The semiconductor device illustrated in FIGS. 19 to 24 may include a component similar to or the same as that of the semiconductor device described with reference to FIGS. 1 to 6. However, unlike the semiconductor device illustrated in FIGS. 1 to 6, the semiconductor device of the present embodiment relates to a structure in which insulating structures DW face each other in the second direction D2 with a first channel pattern CP1 and a second channel pattern CP2 interposed therebetween. In addition, like the semiconductor device illustrated in FIGS. 1 to 6, the semiconductor device of the present embodiment relates to a structure in which both a lower wire BM1 connected to a gate structure GS disposed at one edge of a first device region RX1 and a device separation film SDB penetrating the gate structure GS disposed at the other edge of the first device region RX1 are disposed at the first device region RX1 and a lower wire connected to the gate structure GS disposed at both edges of a second device region RX2 is disposed at the second device region RX2. Contents of the present embodiment overlapping the contents described with reference to FIGS. 1 to 6 will be simplified or omitted, and a difference between the contents of the present embodiment and the contents described with reference to FIGS. 1 to 6 will be mainly described.

Referring to FIGS. 19 to 24, one unit cell of the semiconductor device according to the embodiment may include the first device region RX1 at which the first channel pattern CP1 is disposed, the second device region RX2 at which the second channel pattern CP2 is disposed, and the insulating structures DW facing each other in the second direction D2 with the first channel pattern CP1 and the second channel pattern CP2 interposed therebetween. According to an embodiment, the one unit cell of the semiconductor device may further include a gate separation structure CT separating the first device region RX1 and the second device region RX2.

Referring to FIG. 19 and FIG. 20, gate electrodes 120 extending in the second direction D2 may be separated from each other with respect to the insulating structure DW according to an embodiment. For example, the insulating structure DW may be made of silicon nitride.

According to an embodiment, two insulating structures DW may face each other in the second direction D2 with the first channel pattern CP1 and the second channel pattern CP2 interposed therebetween. In other words, the first and second device regions RX1 and RX2 may be disposed between two insulating structures DW, and boundaries (e.g., upper and lower sides) of the cell may be defined by the insulating structure DW.

According to an embodiment, the insulating structure DW may extend in the first direction D1 from an edge of one side of the first device region RX1 and an edge of one side of the second device region RX2. According to an embodiment, the insulating structure DW, the first device region RX1, the second device region RX2, and the insulating structure DW may be disposed along the second direction D2.

According to an embodiment, the insulating structure DW may be disposed at the edge of the one side of the first device region RX1 and the edge of the one side of the second device region RX2. According to an embodiment, the insulating structure DW may be disposed at an edge of one side (e.g., an upper side) of the first device region RX1. For example, the insulating structure DW may face the gate separation structure CT with the first channel pattern CP1 interposed therebetween. According to an embodiment, the insulating structure DW may be disposed at an edge of one side (e.g., a lower side) of the second device region RX2. For example, the insulating structure DW may face the gate separation structure CT with the second channel pattern CP2 interposed therebetween.

According to an embodiment, the insulating structure DW may be in contact with the first channel pattern CP1 and the second channel pattern CP2 in the second direction D2. In other words, the insulating structure DW may not be spaced apart from the first channel pattern CP1 and the second channel pattern CP2 in the second direction D2.

According to an embodiment, one unit cell of the semiconductor device may include the device separation film SDB that physically separates adjacent cells and/or a lower gate pattern BCB that electrically separates adjacent cells.

Referring to FIG. 19 and FIG. 20, the device separation film SDB may be disposed at one side of the first device region RX1. According to an embodiment, the device separation film SDB may not be disposed at the other side of the first device region RX1. Although FIG. 19, FIG. 20, and FIG. 23 illustrate that the device separation film SDB is disposed at a right side of the first device region RX1 and the device separation film SDB is not disposed at a left side thereof, the present disclosure is not limited thereto, and the device separation film SDB may be disposed at the left side of the first device region RX1 and the device separation film SDB may not be disposed at the right side thereof.

According to an embodiment, the device separation film SDB may penetrate the gate structure GS disposed at one edge of the first device region RX1. According to an embodiment, the device separation film SDB may physically separate the first device region RX1 from a region of another cell adjacent to the first device region RX1.

According to an embodiment, in the first device region RX1, the lower wire BM1 may be connected to the gate structure GS disposed at the other edge of the first device region RX1. According to an embodiment, a first lower gate pattern BCB1 disposed at the other edge of the first device region RX1 may electrically separate the first device region RX1 from a region of another cell adjacent to the first device region RX1 using the first lower gate pattern BCB1 as a boundary. In other words, one side of the first device region RX1 may be physically terminated by the device separation film SDB that is a boundary, and the other side of the first device region RX1 may be electrically separated from the first channel pattern CP1 by the first lower gate pattern BCB1 that is a boundary.

Referring to FIG. 21, the gate structure GS disposed at the other edge of the first device region RX1 may be connected to a first lower wire BM1(VDD) to which a first voltage is applied. For example, the gate structure GS of the first device region RX1 may be connected to the first lower wire BM1(VDD) to which the first voltage is applied through the first lower gate pattern BCB1. The first voltage may be a positive voltage.

According to an embodiment, in the second device region RX2, the lower wire BM1 may be connected to the gate structure GS disposed at both edges of the second device region RX2. According to an embodiment, a second lower gate pattern BCB2 disposed at both edges of the second device region RX2 may electrically separate the second device region RX2 from a region of another cell adjacent to the second device region RX2 using the second lower gate pattern BCB2 as a boundary.

Referring to FIG. 21 and FIG. 22, the gate structure GS included in the second device region RX2 may be connected to a second lower wire BM1(VSS) to which a second voltage is applied. For example, the gate structure GS of the second device region RX2 may be connected to the second lower wire BM1(VSS) to which the second voltage is applied through the second lower gate pattern BCB2. The second voltage may be a negative voltage or a ground voltage.

As described above, the semiconductor device of the present embodiment may include the device separation film SDB disposed at one side of the first device region RX1, the first lower gate pattern BCB1 disposed at the other side of the first device region RX1, and the second lower gate pattern BCB2 connected to the lower wire BM1 at both sides of the second device region RX2, so that leakage of an electric current according to a characteristic of the device is effectively prevented.

As described above, the semiconductor device of the present embodiment may increase a degree of integration of the device because the insulating structure DW disposed outside the first device region RX1 and the second device region RX2 is not spaced apart from the first and second channel patterns CP1 and CP2.

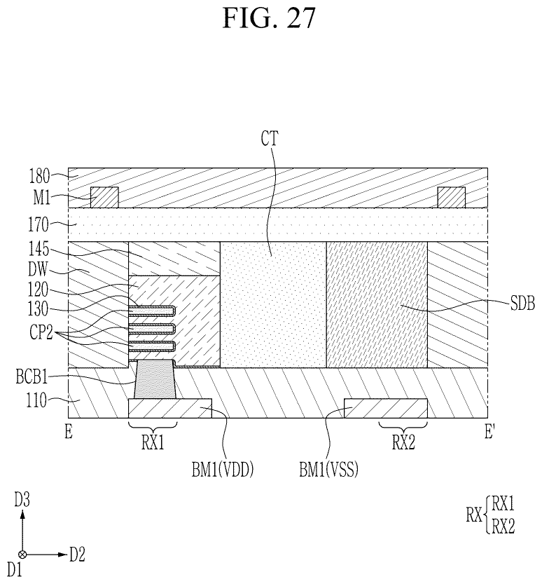

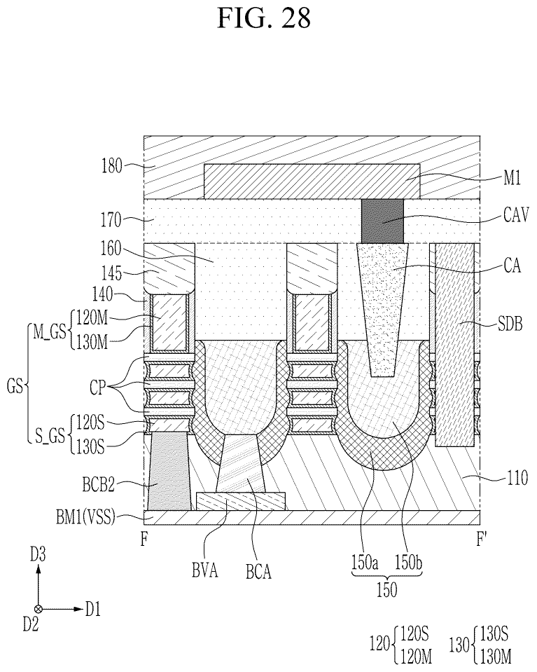

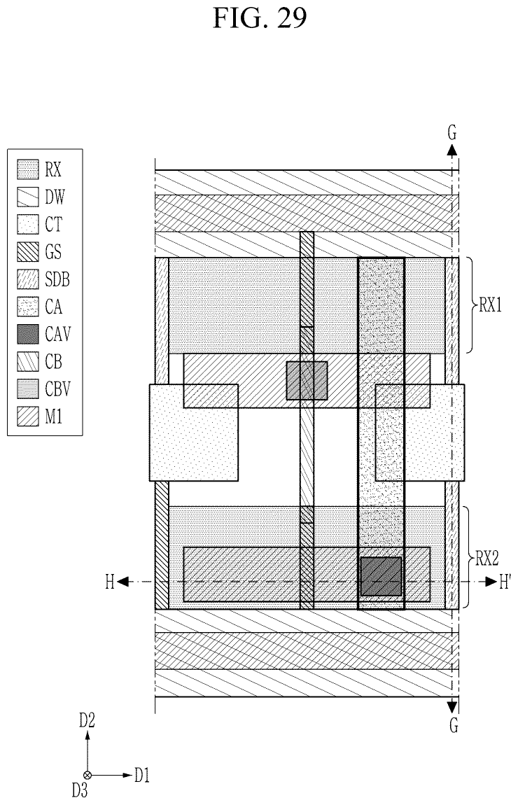

Each of FIG. 25 and FIG. 26 is a layout diagram showing a semiconductor device according to an embodiment of the present disclosure. FIG. 27 is a cross-sectional view of the semiconductor device along line E-E′ of each of FIG. 25 and FIG. 26. FIG. 28 is a cross-sectional view of the semiconductor device along line F-F′ of each of FIG. 25 and FIG. 26.

The semiconductor device illustrated in FIGS. 25 to 28 may include a component similar to or the same as that of the semiconductor device described with reference to FIGS. 1 to 6. However, unlike the semiconductor device illustrated in FIGS. 1 to 6, the semiconductor device of the present embodiment relates to a structure in which insulating structures DW face each other in the second direction D2 with a first channel pattern CP1 and a second channel pattern CP2 interposed therebetween. In addition, unlike the semiconductor device illustrated in FIGS. 1 to 6, the semiconductor device of the present embodiment relates to a structure in which a lower wire connected to a gate structure GS disposed at both edges of a first device region RX1 is disposed at the first device region RX1 included in a unit cell of the semiconductor device is disposed and both a lower wire BM1 connected to the gate structure GS disposed at one edge of a second device region RX2 and a device separation film SDB penetrating the gate structure GS disposed at the other edge of the second device region RX2 are disposed. Contents of the present embodiment overlapping the contents described with reference to FIGS. 1 to 6 will be simplified or omitted, and a difference between the contents of the present embodiment and the contents described with reference to FIGS. 1 to 6 will be mainly described. Contents of the insulating structure DW of the present embodiment overlapping the contents described with reference to FIGS. 19 to 24 will be simplified or omitted.

Referring to FIGS. 25 to 28, one unit cell of the semiconductor device according to the embodiment may include the first device region RX1 at which the first channel pattern CP1 is disposed, the second device region RX2 at which the second channel pattern CP2 is disposed, and the insulating structures DW facing each other in the second direction D2 with the first channel pattern CP1 and the second channel pattern CP2 interposed therebetween. According to an embodiment, the one unit cell of the semiconductor device may further include a gate separation structure CT separating the first device region RX1 and the second device region RX2.

According to an embodiment, the one unit cell of the semiconductor device may include the device separation film SDB that physically separates adjacent cells and/or a lower gate pattern BCB that electrically separates adjacent cells.

Referring to FIG. 25 and FIG. 26, in the first device region RX1, the lower wire BM1 may be connected to the gate structure GS disposed at both edges of the first device region RX1. According to an embodiment, a first lower gate pattern BCB1 disposed at both edges of the first device region RX1 may electrically separate the first device region RX1 from a region of another cell region adjacent to the first device region RX1 using the first lower gate pattern BCB1 as a boundary.

Referring to FIG. 27, the gate structure GS included in the first device region RX1 may be connected to a first lower wire BM1(VDD) to which a first voltage is applied. For example, the gate structure GS of the first device region RX1 may be connected to the first lower wire BM1(VDD) to which the first voltage is applied through the first lower gate pattern BCB1. The first voltage may be a positive voltage.

According to an embodiment, the device separation film SDB may be disposed at one side of the second device region RX2. According to an embodiment, the device separation film SDB may not be disposed at the other side of the second device region RX2. Although FIG. 25, FIG. 26, and FIG. 28 illustrate that the device separation film SDB is disposed at a right side of the second device region RX2 and the device separation film SDB is not disposed at a left side of the second device region RX2, the present disclosure is not limited thereto, and the device separation film SDB may be disposed at the left side of the second device region RX2 and the device separation film SDB may not be disposed at the right side thereof.

According to an embodiment, the device separation film SDB may penetrate the gate structure GS disposed at one edge of the second device region RX2. According to an embodiment, the device separation film SDB may physically separate the second device region RX2 from a region of another cell adjacent to the second device region RX2.

According to an embodiment, in the second device region RX2, the lower wire BM1 may be connected to the gate structure GS disposed at the other edge of the second device region RX2. According to an embodiment, a second lower gate pattern BCB2 disposed at the other edge of the second device region RX2 may electrically separate the second device region RX2 from a region of another cell region adjacent to the second device region RX2 using the second lower gate pattern BCB2 as a boundary. In other words, one side of the second device region RX2 may be physically terminated by the device separation film SDB that is a boundary, and the other side of the second device region RX2 may be electrically terminated by the second lower gate pattern BCB2 that is a boundary.

Although not clearly illustrated in the drawings, the gate structure GS disposed at the other edge of the second device region RX2 may be connected to a second lower wire BM1(VSS) to which a second voltage is applied. For example, the gate structure GS of the second device region RX2 may be connected to the second lower wire BM1(VSS) to which the second voltage is applied through the second lower gate pattern BCB2. The second voltage may be a negative voltage or a ground voltage.

As described above, the semiconductor device of the present embodiment may include the first lower gate pattern BCB1 connected to the lower wire BM1 at both sides of the first device region RX1, the device separation film SDB disposed at one side of the second device region RX2, and the second lower gate pattern BCB2 disposed at the other side of the second device region RX2, so that leakage of an electric current according to a characteristic of the device is effectively prevented.

As described above, the semiconductor device of the present embodiment may increase a degree of integration of the device because the insulating structure DW disposed outside the first device region RX1 and the second device region RX2 is not spaced apart from the first and second channel patterns CP1 and CP2.

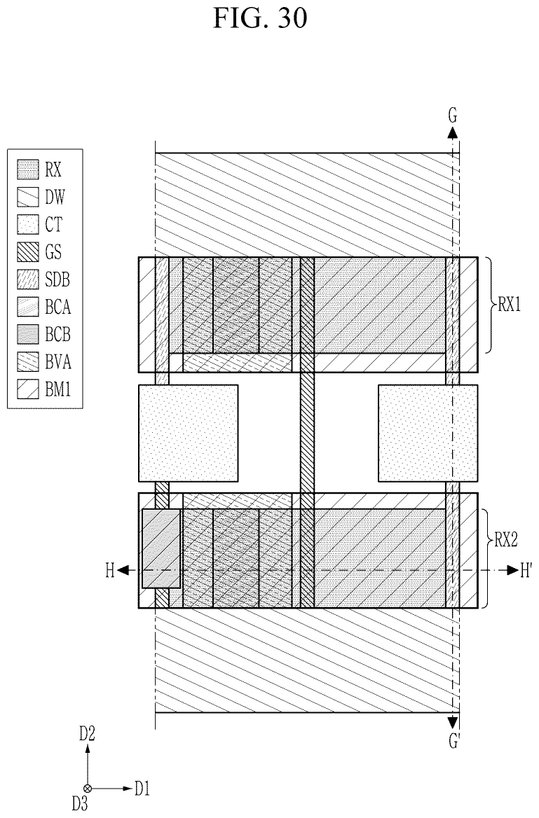

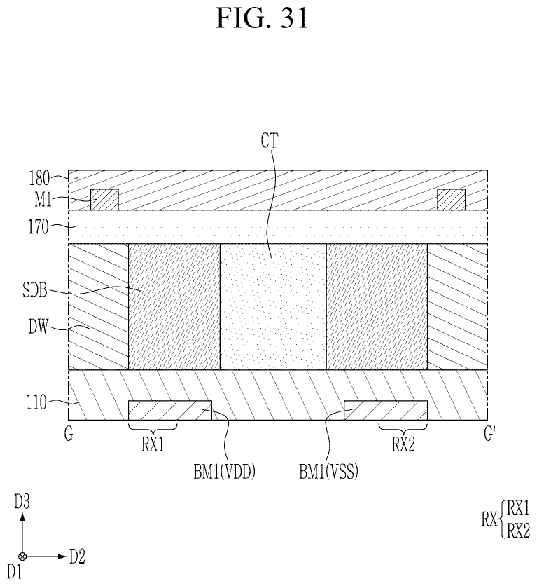

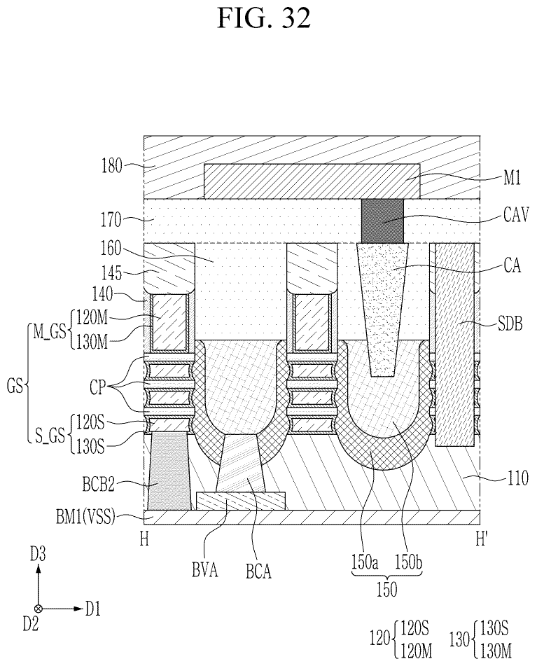

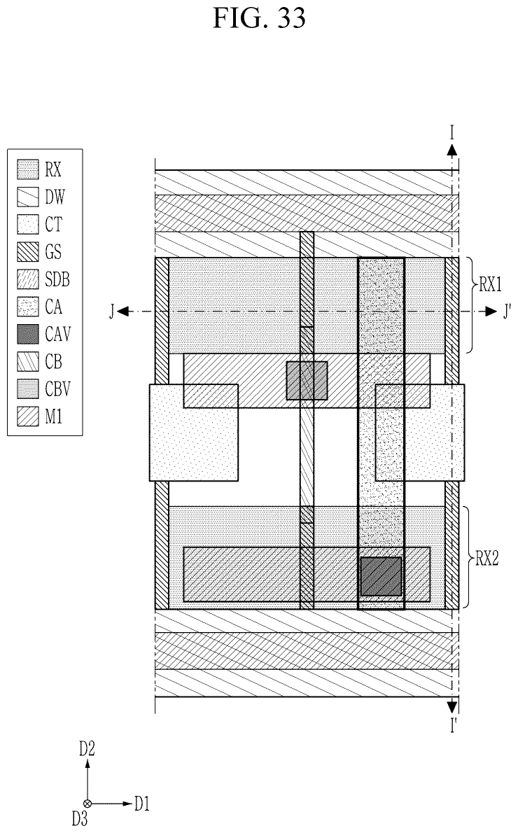

Each of FIG. 29 and FIG. 30 is a layout diagram showing a semiconductor device according to an embodiment of the present disclosure. FIG. 31 is a cross-sectional view of the semiconductor device along line G-G′ of each of FIG. 29 and FIG. 30. FIG. 32 is a cross-sectional view of the semiconductor device along line H-H′ of each of FIG. 29 and FIG. 30.

The semiconductor device illustrated in FIGS. 29 to 32 may include a component similar to or the same as that of the semiconductor device described with reference to FIGS. 1 to 6. However, unlike the semiconductor device illustrated in FIGS. 1 to 6, the semiconductor device of the present embodiment relates to a structure in which insulating structures DW face each other in the second direction D2 with a first channel pattern CP1 and a second channel pattern CP2 interposed therebetween. In addition, unlike the semiconductor device illustrated in FIGS. 1 to 6, the semiconductor device of the present embodiment relates to a structure in which a device separation film SDB penetrating a gate structure GS disposed at both edges of a first device region RX1 is disposed at the first device region RX1 included in a unit cell of the semiconductor device and both a lower wire BM1 connected to the gate structure GS disposed at one edge of the second device region RX2 and the device separation film SDB penetrating the gate structure GS disposed at the other edge of the second device region RX2 are disposed. Contents of the present embodiment overlapping the contents described with reference to FIGS. 1 to 6 will be simplified or omitted, and a difference between the contents of the present embodiment and the contents described with reference to FIGS. 1 to 6 will be mainly described. Contents of the insulating structure DW of the present embodiment overlapping the contents described with reference to FIGS. 19 to 24 will be simplified or omitted.

Referring to FIGS. 29 to 32, one unit cell of the semiconductor device according to the embodiment may include the first device region RX1 at which the first channel pattern CP1 is disposed, the second device region RX2 at which the second channel pattern CP2 is disposed, and the insulating structures DW facing each other in the second direction D2 with the first channel pattern CP1 and the second channel pattern CP2 interposed therebetween. According to an embodiment, the one unit cell of the semiconductor device may further include a gate separation structure CT separating the first device region RX1 and the second device region RX2.

According to an embodiment, the one unit cell of the semiconductor device may include the device separation film SDB that physically separates adjacent cells and/or a lower gate pattern BCB that electrically separates adjacent cells.

Referring to FIG. 29 and FIG. 30, the first device region RX1 may include the device separation film SDB penetrating the gate structure GS disposed at both edges of the first device region RX1. According to an embodiment, the device separation film SDB disposed at both edges of the first device region RX1 may physically separate the first device region RX1 from a region of another cell adjacent to the first device region RX1 using the device separation film SDB as a boundary. In other words, both sides of the first device region RX1 may be physically terminated by the device separation film SDB that is a boundary.

According to an embodiment, the device separation film SDB may be disposed at one side of the second device region RX2. According to an embodiment, the device separation film SDB may not be disposed at the other side of the second device region RX2. Although FIG. 29, FIG. 30, and FIG. 32 illustrate that the device separation film SDB is disposed at a right side of the second device region RX2 and the device separation film SDB is not disposed at a left side of the second device region RX2, the present disclosure is not limited thereto, and the device separation film SDB may be disposed at the left side of the second device region RX2 and the device separation film SDB may not be disposed at the right side thereof.

According to an embodiment, the device separation film SDB may penetrate the gate structure GS disposed at one edge of the second device region RX2. According to an embodiment, the device separation film SDB may physically separate the second device region RX2 from a region of another cell adjacent to the second device region RX2.

According to an embodiment, in the second device region RX2, the lower wire BM1 may be connected to the gate structure GS disposed at the other edge of the second device region RX2. According to an embodiment, a second lower gate pattern BCB2 disposed at the other edge of the second device region RX2 may electrically separate the second device region RX2 from a region of another cell region adjacent to the second device region RX2 using the second lower gate pattern BCB2 as a boundary. In other words, one side of the second device region RX2 may be physically terminated by the device separation film SDB that is a boundary, and the other side of the second device region RX2 may be electrically terminated by the second lower gate pattern BCB2 that is a boundary.

Although not clearly illustrated in the drawings, the gate structure GS disposed at the other edge of the second device region RX2 may be connected to a second lower wire BM1(VSS) to which a second voltage is applied. For example, the gate structure GS of the second device region RX2 may be connected to the second lower wire BM1(VSS) to which the second voltage is applied through the second lower gate pattern BCB2. The second voltage may be a negative voltage or a ground voltage.

As described above, the semiconductor device of the present embodiment may include the device separation film SDB disposed at both sides of the first device region RX1, the device separation film SDB disposed at one side of the second device region RX2, and the second lower gate pattern BCB2 disposed at the other side of the second device region RX2, so that leakage of an electric current according to a characteristic of the device is effectively prevented.

As described above, the semiconductor device of the present embodiment may increase a degree of integration of the device because the insulating structure DW disposed outside the first device region RX1 and the second device region RX2 is not spaced apart from the first and second channel patterns CP1 and CP2.

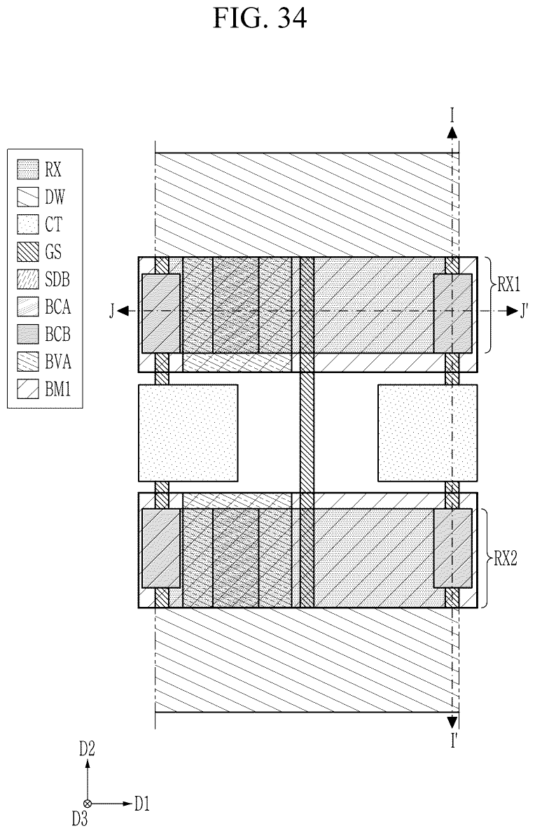

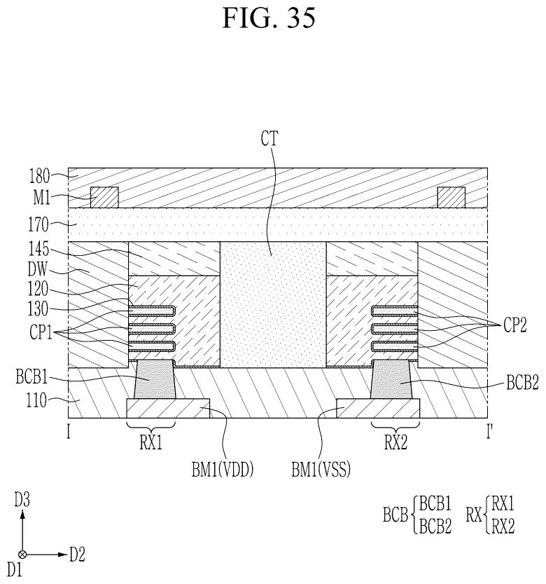

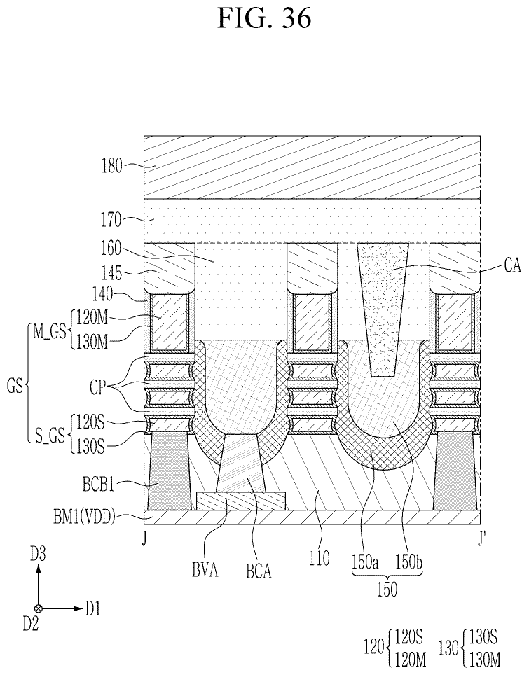

Each of FIG. 33 and FIG. 34 is a layout diagram showing a semiconductor device according to an embodiment of the present disclosure. FIG. 35 is a cross-sectional view of the semiconductor device along line I-I′ of each of FIG. 33 and FIG. 34. FIG. 36 is a cross-sectional view of the semiconductor device along line J-J′ of each of FIG. 33 and FIG. 34.

The semiconductor device illustrated in FIGS. 33 to 36 may include a component similar to or the same as that of the semiconductor device described with reference to FIGS. 1 to 6. However, unlike the semiconductor device illustrated in FIGS. 1 to 6, the semiconductor device of the present embodiment relates to a structure in which insulating structures DW face each other in the second direction D2 with a first channel pattern CP1 and a second channel pattern CP2 interposed therebetween. In addition, unlike the semiconductor device illustrated in FIGS. 1 to 6, the semiconductor device of the present embodiment relates to a structure in which a lower wire BM1 connected to a gate structure GS disposed at both edges of each of a first device region RX1 and a second device region RX2 is disposed at each of the first device region RX1 and the second device region RX2 included in a unit cell of the semiconductor device. Contents of the present embodiment overlapping the contents described with reference to FIGS. 1 to 6 will be simplified or omitted, and a difference between the contents of the present embodiment and the contents described with reference to FIGS. 1 to 6 will be mainly described. Contents of the insulating structure DW of the present embodiment overlapping the contents described with reference to FIGS. 19 to 24 will be simplified or omitted.

Referring to FIGS. 33 to 36, one unit cell of the semiconductor device according to the embodiment may include the first device region RX1 at which the first channel pattern CP1 is disposed, the second device region RX2 at which the second channel pattern CP2 is disposed, and the insulating structures DW facing each other in the second direction D2 with the first channel pattern CP1 and the second channel pattern CP2 interposed therebetween. According to an embodiment, the one unit cell of the semiconductor device may further include a gate separation structure CT separating the first device region RX1 and the second device region RX2.

According to an embodiment, the one unit cell of the semiconductor device may include a lower gate pattern BCB that electrically separates adjacent cells.

Referring to FIG. 33 and FIG. 34, in the first and second device regions RX1 and RX2, the lower wire BM1 may be connected to the gate structure GS disposed at both edges of each of the first and second device regions RX1 and RX2.

According to an embodiment, a first lower gate pattern BCB1 disposed at both edges of the first device region RX1 may electrically separate the first device region RX1 from a region of another cell region adjacent to the first device region RX1 using the first lower gate pattern BCB1 as a boundary.

According to an embodiment, a second lower gate pattern BCB2 disposed at both edges of the second device region RX2 may electrically separate the second device region RX2 from a region of another cell adjacent to the second device region RX2 using the second lower gate pattern BCB2 as a boundary.

Referring to FIG. 35, the gate structure GS disposed at an edge of the first device region RX1 may be connected to a first lower wire BM1(VDD) to which a first voltage is applied. For example, the gate structure GS of the first device region RX1 may be connected to the first lower wire BM1(VDD) to which the first voltage is applied through the first lower gate pattern BCB1. The first voltage may be a positive voltage. According to an embodiment, the gate structure GS disposed at an edge of the second device region RX2 may be connected to a second lower wire BM1(VSS) to which a second voltage is applied. For example, the gate structure GS of the second device region RX2 may be connected to the second lower wire BM1(VSS) to which the second voltage is applied through the second lower gate pattern BCB2. The second voltage may be a negative voltage or a ground voltage.

As described above, the semiconductor device of the present embodiment may prevent leakage of an electric current by electrically separating the first and second channel patterns CP1 and CP2 using the lower gate pattern BCB as a boundary.

As described above, the semiconductor device of the present embodiment may include the insulating structure DW in contact with the first and second channel patterns CP1 and CP2 between the first device region RX1 and the second device region RX2, so that it is possible to increase a degree of integration of the device.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

What is claimed is:

1. A semiconductor device comprising:
a substrate that includes a first surface and a second surface facing each other and includes a first device region and a second device region at which different conductivity types of devices are disposed;
a first channel pattern and a second channel pattern that are each disposed above the first surface of the substrate at the first device region and the second device region;
an insulating structure that extends in a first direction between the first device region and the second device region;
gate structures that surround the first channel pattern and the second channel pattern and extend in a second direction intersecting the first direction;
source/drain patterns that are connected to both sides of each of the first channel pattern and the second channel pattern;
a lower wire that is disposed on the second surface of the substrate and is connected to at least some of the source/drain patterns and the gate structure disposed at one edge of the first device region; and
a device separation film that penetrates the gate structure disposed at the other edge of the first device region.

2. The semiconductor device of claim 1,
wherein one side of the insulating structure contacts the first channel pattern in the second direction, and the other side of the insulating structure contacts the second channel pattern in the second direction.

3. The semiconductor device of claim 1, wherein a P-type device is disposed at the first device region and an N-type device is disposed at the second device region.

4. The semiconductor device of claim 3, wherein the second device region does not include the device separation film and includes lower gate patterns connecting the gate structures disposed at both edges of the second device region and the lower wire.

5. The semiconductor device of claim 1, wherein a P-type device is disposed at the first device region, the lower wire includes a first lower wire to which a first voltage is applied and a second lower wire to which a second voltage lower than the first voltage is applied, and the first device region includes a lower gate pattern connecting the gate structure disposed at one edge of the first device region and the first lower wire.

6. The semiconductor device of claim 1,
wherein an N-type device is disposed at the first device region,
the lower wire includes a first lower wire to which a first voltage is applied and a second lower wire to which a second voltage lower than the first voltage is applied, and the first device region includes a lower gate pattern connecting the gate structure disposed at one edge of the first device region and the second lower wire.

7. The semiconductor device of claim 1, further comprising gate separation structures that are spaced apart from the first channel pattern and the second channel pattern in the second direction,
wherein some of the gate separation structures face the insulating structure with the first channel pattern interposed therebetween, and some of the gate separation structures face the insulating structure with the second channel pattern interposed therebetween.

8. The semiconductor device of claim 1,
wherein the first device region and the second device region are disposed within one standard cell.

9. A semiconductor device comprising:
a substrate that includes a first surface and a second surface facing each other and includes a first device region and a second device region at which different conductivity types of devices are disposed;
a first channel pattern and a second channel pattern that are each disposed above the first surface of the substrate at the first device region and the second device region;
insulating structures that extend in a first direction with the first channel pattern and the second channel pattern interposed therebetween and face each other in a second direction intersecting the first direction;
gate structures that surround the first channel pattern and the second channel pattern and extend in the second direction;
source/drain patterns that are connected to both sides of each of the first channel pattern and the second channel pattern;
a lower wire that is disposed on the second surface of the substrate and is connected to at least some of the source/drain patterns and the gate structure disposed at one edge of the first device region; and
a device separation film that penetrates the gate structure disposed at the other edge of the first device region.

10. The semiconductor device of claim 9, wherein each of the insulating structures contacts the first channel pattern and the second channel pattern in the second direction.

11. The semiconductor device of claim 9, wherein a P-type device is disposed at the first device region and an N-type device is disposed at the second device region.

12. The semiconductor device of claim 11, wherein the second device region does not include the device separation film and includes lower gate patterns connecting the gate structures disposed at both edges of the second device region and the lower wire.

13. The semiconductor device of claim 9, wherein a P-type device is disposed at the first device region, the lower wire includes a first lower wire to which a first voltage is applied and a second lower wire to which a second voltage lower than the first voltage is applied, and the first device region includes a lower gate pattern connecting the gate structure disposed at one edge of the first device region and the first lower wire.

14. The semiconductor device of claim 9, wherein an N-type device is disposed at the first device region, the lower wire includes a first lower wire to which a first voltage is applied and a second lower wire to which a second voltage lower than the first voltage is applied, and the first device region includes a lower gate pattern connecting the gate structure disposed at one edge of the first device region and the second lower wire.

15. The semiconductor device of claim 9, further comprising a gate separation structure that is disposed between the first device region and the second device region,
wherein the gate separation structure is spaced apart from the first channel pattern and the second channel pattern in the second direction.

16. The semiconductor device of claim 9,
wherein the first device region and the second device region are disposed within one standard cell.

17. A semiconductor device comprising:
a substrate that includes a first surface and a second surface facing each other and includes a first device region and a second device region at which different conductivity types of devices are disposed;
a first channel pattern and a second channel pattern that are disposed above the first surface of the substrate at the first device region and the second device region, respectively;
at least one insulating structure that extends in a first direction and is disposed adjacent to at least one of the first channel pattern and the second channel pattern in a second direction intersecting the first direction;
gate structures that surround the first channel pattern and the second channel pattern and extend in the second direction;
source/drain patterns that are connected to both sides of each of the first channel pattern and the second channel pattern; and
a lower wire that is disposed on the second surface of the substrate, is connected to at least some of the source/drain patterns, and is connected to the gate structures disposed at both edges of the first device region and the second device region.

18. The semiconductor device of claim 17,
wherein the at least one insulating structure contacts the first channel pattern and the second channel pattern in the second direction and extends in the first direction between the first device region and the second device region.

19. The semiconductor device of claim 17,
wherein the at least one insulating structure contacts the first channel pattern and the second channel pattern in the second direction and faces with the first channel pattern and the second channel pattern interposed therebetween.

20. The semiconductor device of claim 17,
wherein a P-type device is disposed at the first device region and an N-type device is disposed at the second device region,
the lower wire includes a first lower wire to which a first voltage is applied and a second lower wire to which a second voltage lower than the first voltage is applied,
the first device region includes a lower gate pattern connecting the gate structure disposed at one edge of the first device region and the first lower wire, and
the second device region includes a lower gate pattern connecting the gate structure disposed at one edge of the second device region and the first lower wire.
